(19) United States
(12) Patent Application Publication
(10) Pub. No.: US 2026/0190458 A1
(43) Pub. Date: Jul. 2, 2026

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jhon-Jhy LIAW, Zhudong Township (TW)

(73) Assignee: TAIWAN SEMICONDUCTOR MANUFACTURING COMPANY, LTD., Hsinchu (TW)

(21) Appl. No.: 19/004,127

(22) Filed: Dec. 27, 2024

(51) Int. Cl. H10D 84/83; H10D 30/01; H10D 30/43; H10D 62/10; H10D 62/13; H10D 64/01; H10D 64/23; H10D 84/01

(52) U.S. Cl. CPC H10D 84/8312; H10D 30/014; H10D 30/0191; H10D 30/43; H10D 62/115; H10D 62/121; H10D 62/151; H10D 64/017; H10D 64/021; H10D 64/258; H10D 84/0128; H10D 84/013; H10D 84/0135; H10D 84/0149; H10D 84/832

(57) ABSTRACT

A semiconductor structure includes a first transistor and a second transistor. The first transistor includes first nanostructures, a first gate structure wrapped around the first nanostructures, first source/drain features attached to opposite sides of the first nanostructures, and first source/drain contacts partially extending into the first source/drain features. The second transistor includes second nanostructures, a second gate structure wrapped around the second nanostructures, second source/drain features attached to opposite sides of the second nanostructures, and second source/drain contacts partially extending into the second source/drain features. The second dimension of the second source/drain features is greater than the first dimension of the first source/drain features. The second width of the second source/drain contacts is greater than the first width of the first source/drain contacts, and the second depth of the second source/drain contacts is less than the first depth of the first source/drain contacts.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 2B, 3A, 3B, 4A, and 4B are perspective views of a workpiece at various fabrication stages, in accordance with some embodiments of the present disclosure.

FIGS. 5A, 6A, 7A, 8A, 9A, 10A, 11A, 12A, 13A, 14A, 15A, 16A, 17A, and 18A are X-Z cross-sectional views of the workpiece at various fabrication stages along a line A-A′ of FIG. 4A, in accordance with some embodiments of the present disclosure.

FIGS. 5B, 6B, 7B, 8B, 9B, 10B, 11B, 12B, 13B, 14B, 15B, 16B, 17B, and 18B are Y-Z cross-sectional views of the workpiece at various fabrication stages along a line B-B′ of FIG. 4A, in accordance with some embodiments of the present disclosure.

FIGS. 5C, 10C, 11C, and 18C are Y-Z cross-sectional views of the workpiece at various fabrication stages along a line C-C′ of FIG. 4A, in accordance with some embodiments of the present disclosure.

FIGS. 5D, 6C, 7C, 8C, 9C, 10D, 11D, 12C, 13C, 14C, 15C, 16C, 17C, and 18D are X-Z cross-sectional views of the workpiece at various fabrication stages along a line D-D′ of FIG. 4B, in accordance with some embodiments of the present disclosure.

FIGS. 5E, 6D, 7D, 8D, 9D, 10E, 11E, 12D, 13D, 14D, 15D, 16D, 17D, and 18E are Y-Z cross-sectional views of the workpiece at various fabrication stages along a line E-E′ of FIG. 4B, in accordance with some embodiments of the present disclosure.

FIGS. 5F, 10F, 11F, and 18F are Y-Z cross-sectional views of the workpiece at various fabrication stages along a line F-F′ of FIG. 4B, in accordance with some embodiments of the present disclosure.

FIGS. 19A and 19B are an X-Z cross-sectional view and a Y-Z cross-sectional view of the workpiece at a fabrication stage along lines A-A′ and B-B′ of FIG. 4A, respectively, in accordance with some alternative embodiments of the present disclosure.

FIGS. 20A and 20B are an X-Z cross-sectional view and a Y-Z cross-sectional view of a semiconductor structure along lines A-A′ and C-C′ of FIG. 4A, respectively, in accordance with alternative embodiments of the present disclosure.

FIGS. 20C and 20D are an X-Z cross-sectional view and a Y-Z cross-sectional view of a semiconductor structure along lines D-D′ and F-F′ of FIG. 4B, respectively, in accordance with alternative embodiments of the present disclosure.

FIG. 21 is a Y-Z cross-sectional view of a semiconductor structure along line B-B′ of FIG. 4A, in accordance with alternative embodiments of the present disclosure.

FIG. 22 is a Y-Z cross-sectional view of a semiconductor structure along line E-E′ of FIG. 4B, in accordance with alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The GAA transistor structures described below may be patterned by any suitable method. For example, the structures may be patterned by using one or more photolithography processes, including double-patterning processes or multi-patterning processes. In general, double-patterning processes or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structures.

The critical poly pitch (CPP), which means a pitch between a gate and an adjacent gate, of the GAA transistor is scaled down as the entire dimension of the GAA transistor continue to scale down. In the same wafer or chip, there may be multiple transistors with different CPP for different applications, such as small CPP devices (e.g., transistors with small CPP) and large CPP devices (e.g., transistors with large CPP). Generally, since the devices in the same wafer or chip undergo the same process, the dimensions of the source/drain (S/D) contacts extending in the S/D features are substantially the same in both the small CPP devices and the large CPP devices. However, implementing S/D contacts with the same dimensions in both the small CPP devices and the large CPP devices may cause some issues.

For example, wider S/D contacts (i.e., the S/D contacts extending wider in S/D features) may be required in the large CPP devices. However, since the S/D features of small CPP devices have small widths, if the wider S/D contacts are also formed in small CPP devices, the wider S/D contacts may contact the second epitaxial layers (the epitaxial layers grown from the nanostructures) of the S/D features or contact the inner gate portions (i.e., portions of gate structures that formed between the nanostructures). Since the second epitaxial layers have higher resistance than third epitaxial layers (the epitaxial layer grown from the second epitaxial layers) of the S/D features, the direct contact between the wider S/D contacts and the second epitaxial layers increases the contact resistance (Rc) and causes current crowding, which also increases the Rc. Moreover, the contact between the wider S/D contacts and the inner gate portions may cause a short-circuit, which might result in a decreased yield. On the other hand, implementing the narrower S/D contacts (i.e., the S/D contacts extending narrower in S/D features) in both the small CPP devices and the large CPP devices cannot provide enough contact area between the S/D contacts and the S/D features, and thus the Rc cannot be improved.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that have deeper and narrower S/D contacts in the small CPP devices, and have shallower and wider S/D contacts in the large CPP devices. In this way, it can avoid the contact between the S/D contacts and the second epitaxial layer, and thus avoid the increased Rc in both the small CPP devices and the large CPP devices. Moreover, it can also avoid the contact between the S/D contacts and the inner gate portions, and thus avoid the negative impact on the yield. On the other hand, since the S/D features of the small CPP devices have deeper depths, it can provide more contact area between the S/D contacts and the S/D features, so as to reduce the Rc in small CPP devices. In addition, since the S/D features of the large CPP devices have large widths to allocate to the wider S/D contacts, the wider S/D contacts can be implemented in the large CPP devices to increase the contact area between the S/D contacts and the S/D features, so as to reduce the Rc in the large CPP devices. As a result, the device performances in the small CPP devices and the large CPP devices can be optimized individually and simultaneously.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

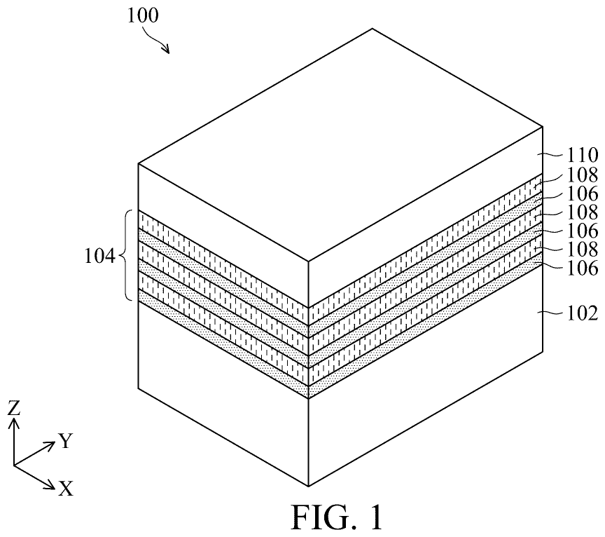

FIGS. 1, 2A, 2B, 3A, 3B, 4A, and 4B are perspective views of a workpiece 100 at various fabrication stages, in accordance with some embodiments. Referring to FIG. 1, the workpiece 100 is provided. The workpiece 100 includes a substrate 102 and a stack 104 over the substrate 102. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type well regions and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

In some embodiments, the stack 104 includes semiconductor layers 106 and semiconductor layers 108 that are stacked in an alternating manner in the Z-direction. The semiconductor layers 106 and the semiconductor layers 108 may have different semiconductor compositions. In some embodiments, the semiconductor layers 106 are formed of silicon germanium, and the semiconductor layers 108 are formed of silicon. In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and the semiconductor layers 108 are deposited alternatingly, one-after-another, to form the stack 104. It should be noted that, three layers of the semiconductor layers 106 and three layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer structure or a multi-layer structure. In some embodiments, the hard mask layer 110 is a single layer structure and includes a silicon germanium layer. In some embodiments, the hard mask layer 110 is a multi-layer structure and includes a silicon nitride layer and a silicon oxide layer over the silicon nitride layer.

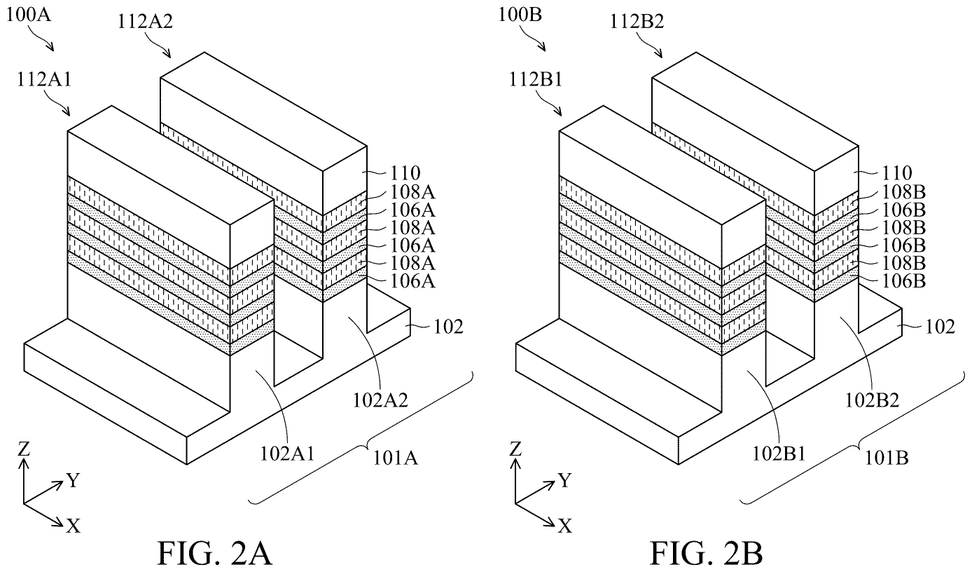

Referring to FIGS. 2A and 2B, the workpiece 100 is formed into semiconductor structures 100A and 100B, in accordance with some embodiments. In some embodiments, the semiconductor structure 100A is formed in the region 101A of the workpiece 100, and the semiconductor structure 100B is formed in the region 101B of the workpiece 100. In some embodiments, the substrate 102, the stack 104, and the hard mask layer 110 are patterned to form fin structures 112A1 and 112A2 of the semiconductor structure 100A in the region 101A, and form fin structures 112B1 and 112B2 of the semiconductor structure 100B in the region 101B, as shown in FIGS. 2A and 2B. In some embodiments, the devices (e.g., GAA transistors) formed from the semiconductor structure 100A in the region 101A have smaller critical poly pitch (CPP), and the devices (e.g., GAA transistors) formed from the semiconductor structure 100B in the region 101B have larger CPP, which will be described in more detail below.

In some embodiments, in the semiconductor structure 100A, each of the fin structures 112A1 and 112A2 includes a base portion (e.g., base fins 102A1 and 102A2) formed from a portion of the substrate 102 and a stack portion formed from the stack 104 over the base portion, as shown in FIG. 2A. The stack portion may include the semiconductor layers 106A and the semiconductor layers 108A that are stacked in an alternating manner over the substrate 102, wherein the semiconductor layers 106A and 108A are formed from the semiconductor layers 106 and 108, respectively. In some embodiments, the base fins 102A1 and 102A2 protrude from the substrate 102. Each of the fin structures 112A1 and 112A2 extends lengthwise in the X-direction and extends vertically in the Z-direction over the substrate 102, and arranged in the Y-direction. In some embodiments, widths of the fin structures 112A1 and 112A2 along the Y-direction are the same. Although the two fin structures 112A1 and 112A2 are formed and shown herein, more fin structures may be formed, such as three or more fin structures.

In some embodiments, in the semiconductor structure 100B, each of the fin structures 112B1 and 112B2 includes a base portion (e.g., base fins 102B1 and 102B2) formed from a portion of the substrate 102 and a stack portion formed from the stack 104 over the base portion, as shown in FIG. 2B. The stack portion may include the semiconductor layers 106B and the semiconductor layers 108B that are stacked in an alternating manner over the substrate 102, wherein the semiconductor layers 106B and 108B are formed from the semiconductor layers 106 and 108, respectively. In some embodiments, the base fins 102B1 and 102B2 protrude from the substrate 102. Each of the fin structures 112B1 and 112B2 extends lengthwise in the X-direction and extends vertically in the Z-direction over the substrate 102, and arranged in the Y-direction. In some embodiments, widths of the fin structures 112B1 and 112B2 along the Y-direction are the same. In some embodiments, widths of the fin structures 112B1 and 112B2 are greater than the fin structures 112A1 and 112A2 along the Y-direction. Although the two fin structures 112B1 and 112B2 are formed and shown herein, more fin structures may be formed, such as three or more fin structures.

The fin structures 112A1, 112A2, 112B1, and 112B2 (which may collectively be referred to as fin structures 112) may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 112 by etching the stack 104 and the substrate 102. The etching process may include dry etching, wet etching, reactive ion etching (RIE), and/or other suitable processes. In some embodiments, the lithography processes may include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam (e-beam) writing, and ion-beam writing.

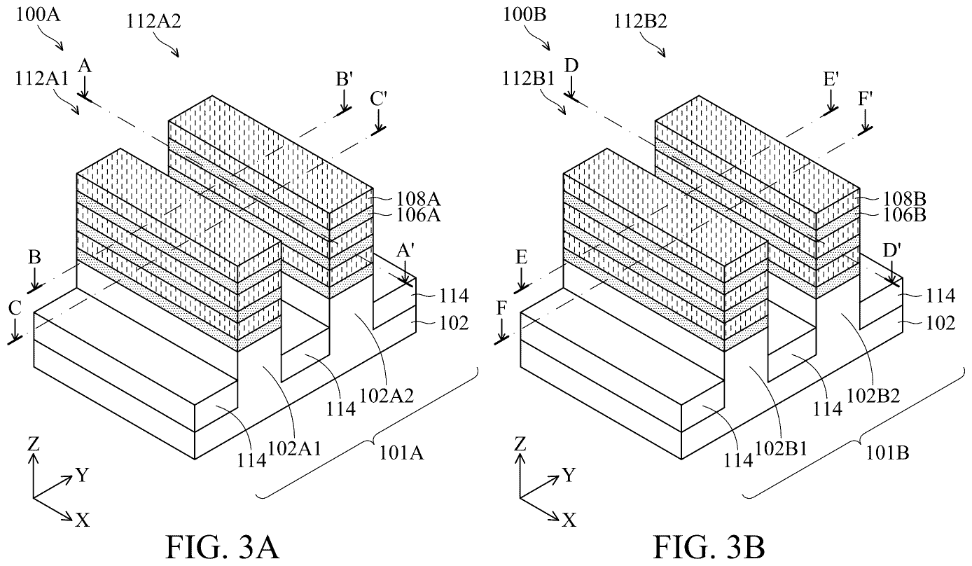

Referring to FIGS. 3A and 3B, after the formation of the fin structures 112, isolation structures 114 are formed, in accordance with some embodiments. In some embodiments, after the fin structures 112 are formed, the hard mask layer 110 over the fin structures 112 is removed and the isolation structures 114 are formed over the substrate 102. In some embodiments, the isolation structures 114 are formed between the fin structures 112. In other embodiments, the isolation structures 114 are formed around the fin structures 112. More specifically, the isolation structures 114 are formed between and around the base fins (e.g., base fins 102A1, 102A2, 102B1, and 102B2) of the fin structures 112. The isolation structures 114 may also be referred to as shallow trench isolation (STI) features.

In some embodiments, a dielectric material for the isolation structures 114 is first deposited over the workpiece 100. Specifically, the dielectric material is deposited and formed over the fin structures 112 and the substrate 102 to cover the fin structures 112 and the substrate 102. In some embodiments, the dielectric material is formed to wrap around the fin structures 112. In some embodiments, the dielectric material may include silicon oxide (SiO₂), silicon nitride (Si₃N₄), silicon oxynitride (SiON), fluorine-doped silicate glass (FSG), a low-k dielectric material, other suitable materials, or combinations thereof. Exemplary low-k dielectric materials may include carbon doped silicon oxide, xerogel, aerogel, amorphous fluorinated carbon, parylene, BCB-based dielectric material, polyimide, other low-k dielectric materials, or combinations thereof.

In some embodiments, the dielectric material is deposited using a deposition process, such as CVD, subatmospheric CVD (SACVD), flowable CVD (FCVD), ALD, spin-on coating, and/or other suitable process. The deposited dielectric material is then thinned and planarized, for example by a chemical mechanical polishing (CMP) process, until the hard mask layer 110 is removed. The planarized dielectric material is further recessed by a dry etching process, a wet etching process, and/or a combination thereof to form the isolation structures 114. In some embodiments, before forming the isolation structures 114, liner layers may be conformally deposited over the substrate 102 using a deposition process, such as CVD, ALD, PECVD, high-density plasma CVD (HDPCVD), MOCVD, RPCVD, LPCVD, atomic layer CVD (ALCVD), atmospheric pressure CVD (APCVD), FCVD, or combinations thereof.

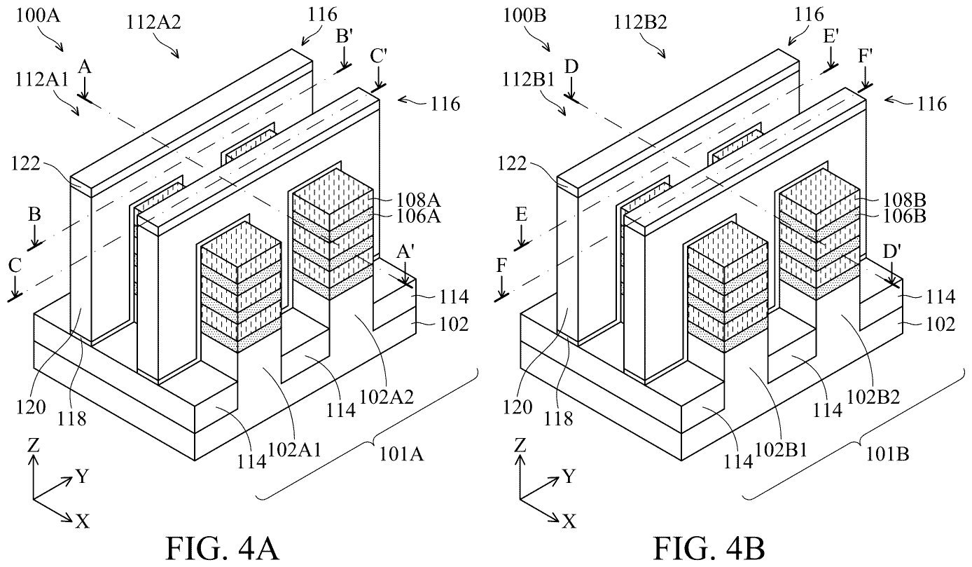

Referring to FIGS. 4A and 4B, dummy gate structures 116 may be formed over the fin structures 112 and over the isolation structures 114, in accordance with some embodiments. The dummy gate structures 116 may be configured to extend lengthwise in the Y-direction and wrap around top surfaces and side surfaces of the fin structures 112. In some embodiments, in order to form the dummy gate structures 116, a dummy gate dielectric material for dummy gate dielectric layers 118 is first formed over the fin structures 112 and over the isolation structures 114. In some embodiments, the dummy gate dielectric layers 118 may include a dielectric material such as a nitride (e.g., Si₃N₄, SiON), a carbide (e.g., silicon carbide (SiC)), an oxide (e.g., SiO₂), or some other suitable materials.

Then, in some embodiments, a dummy gate electrode material for dummy gate electrode layers 120 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard mask layers 122 are formed over the dummy gate electrode material. In some embodiments, the hard mask layers 122 may be formed by using photolithography and removal (e.g., etching) processes. In some embodiments, the hard mask layers 122 may include photoresist materials or hard mask materials. In some embodiments, each of the hard mask layers 122 may include multiple layers, such as a silicon nitride layer and a silicon oxide layer. After the formation of the hard mask layers 122, a removal process (e.g., etching) may be performed to remove portions of the dummy gate electrode material and the dummy gate dielectric material that are not directly underlie the hard mask layers 122, thereby forming the dummy gate electrode layers 120 and the dummy gate dielectric layers 118 to constitute the dummy gate structures 116. Each of the dummy gate structures 116 has the dummy gate dielectric layer 118, the dummy gate electrode layer 120, and the hard mask layer 122.

The dummy gate structures 116 may undergo a gate replacement process through subsequent processing to form metal gates, such as a high-k metal gate, as discussed in greater detail below. FIGS. 4A and 4B show that each the semiconductor structures 100A and 100B has two dummy gate structures 116. In some embodiments, in the semiconductor structures 100A and 100B, less or more dummy gate structures may be formed for one or more transistors sharing source/drain regions.

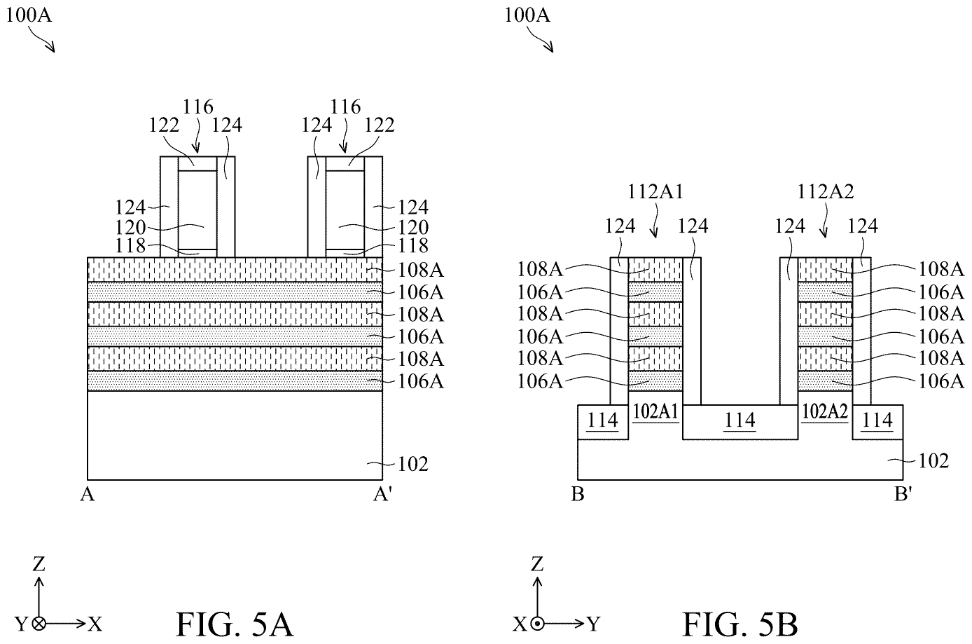

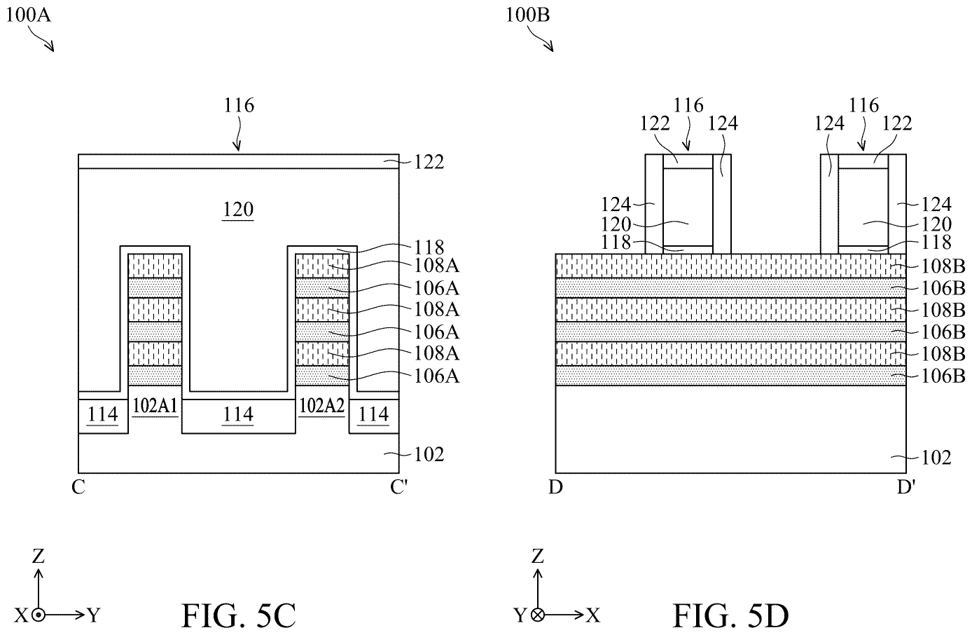

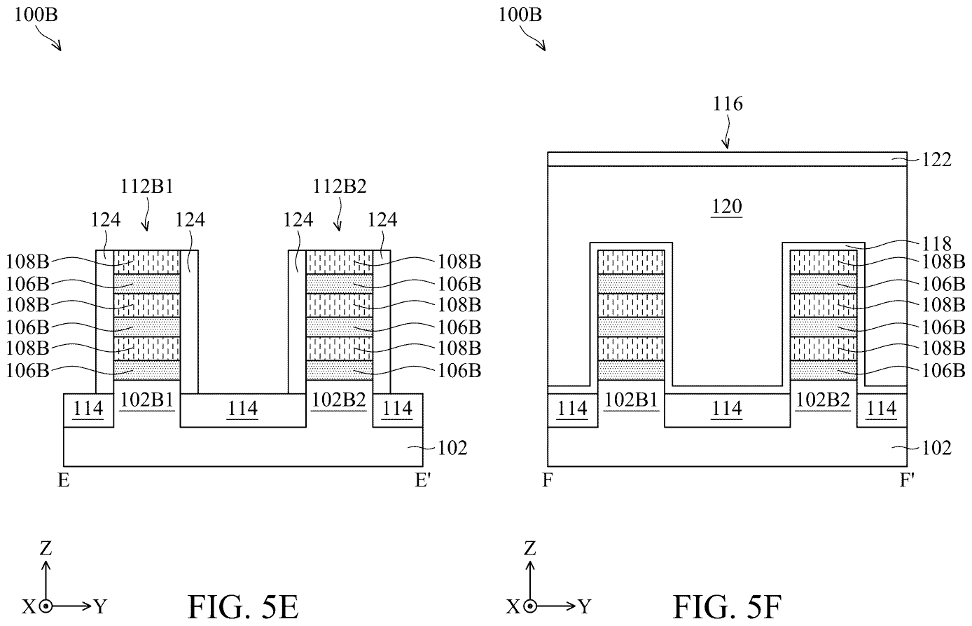

Referring to FIGS. 5A to 5F, after the formation of the dummy gate structures 116, gate spacers 124 are formed on sidewalls of the dummy gate structures 116, in accordance with some embodiments. FIGS. 4A, 4B, and 4C are cross-sectional views of the semiconductor structure 100A along lines A-A′, B-B′, and C-C′ of FIG. 4A, respectively. FIGS. 4D, 4E, and 4F are cross-sectional views of the semiconductor structure 100B along lines D-D′, E-E′, and F-F′ of FIG. 4B, respectively.

In some embodiments, the gate spacers 124 are formed on opposite sidewalls of the fin structures 112 in the Y-direction, on opposite sidewalls of the dummy gate structures 116 in the X-direction, and over top surfaces of the topmost semiconductor layers 108A and 108B. The gate spacers 124 may include Si₃N₄, SiO₂, SiC, silicon oxycarbide (SiOC), SiON, silicon carbon nitride (SiCN), silicon oxycarbon nitride (SiOCN), carbon doped oxide, nitrogen doped oxide, porous oxide, or combinations thereof. In some embodiments, the gate spacers 124 include a low-k dielectric material, such as those described herein. The gate spacers 124 may include a single layer or a multi-layer structure.

In some embodiments, the gate spacers 124 may be formed by conformally depositing a spacer layer (containing the dielectric material) over the fin structures 112 and the dummy gate structures 116. Then, an anisotropic etching process is performed to remove horizontal portions of the spacer layer from the top surfaces of the isolation structures 114, the fin structures 112, and the dummy gate structures 116. After the anisotropic etching process, the portions of the spacer layer formed on sidewall surfaces of the fin structures 112 and the dummy gate structures 116 substantially remain and become the gate spacers 124. In some embodiments, the anisotropic etching process is a dry (e.g., plasma) etching process. Additionally or alternatively, the formation of the gate spacers 124 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The gate spacers 124 may also be interchangeably referred to as top spacers.

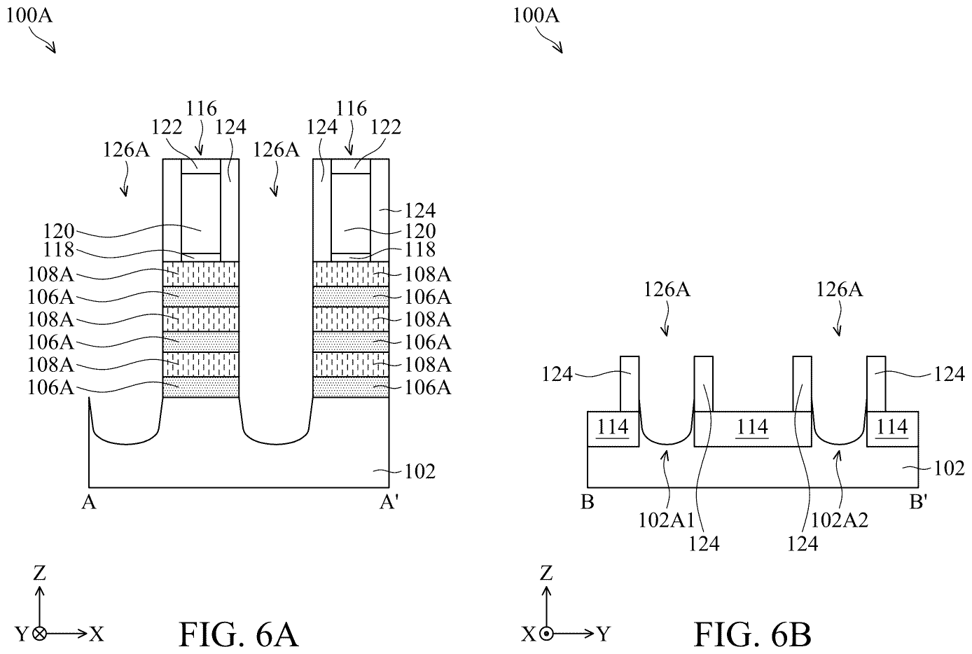

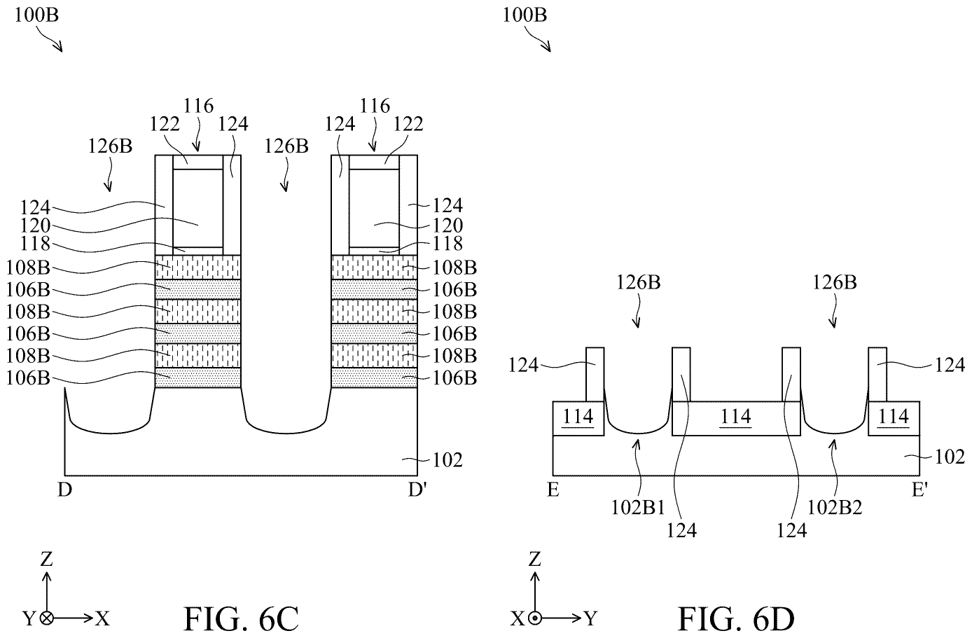

Referring to FIGS. 6A to 6D, the fin structures 112 are recessed to form source/drain trenches in the fin structures 112 (or passing through the semiconductor layers 106A, 106B and 108A, 108B) for source/drain regions, in accordance with some embodiments. FIGS. 6A and 6B are cross-sectional views of the semiconductor structure 100A along lines A-A′ and B-B′ of FIG. 4A, respectively. FIGS. 6C and 6D are cross-sectional views of the semiconductor structure 100B along lines D-D′ and E-E′ of FIG. 4B, respectively.

In some embodiments, in the semiconductor structure 100A, the source/drain trenches 126A are formed on opposite sides of the dummy gate structures 116 in the X-direction. In some embodiments, in the semiconductor structure 100B, the source/drain trenches 126B are formed on opposite sides of the dummy gate structures 116 in the X-direction. Specifically, the source/drain trenches 126A and 126B may be formed by performing one or more etching processes to remove portions of the semiconductor layers 106A, 106B, 108A, and 108B and the substrate 102 (e.g., base fins 102A1, 102A2, 102B1, and 102B2) that the dummy gate structures 116 and the gate spacers 124 do not cover or vertically overlap.

In some embodiments, a single etchant is used to remove the semiconductor layers 106A, 106B, 108A, and 108B and the substrate 102. In other embodiments, multiple etchants may be used to perform the etching process. In some embodiments, portions of the substrate 102 are etched, so that the source/drain trenches 126A and 126B (which may collectively be referred to as source/drain trenches 126) extend into the substrate, and each has a concave surface in the substrate 102, as shown in FIGS. 6A to 6D. In some embodiments, portions of the gate spacers 124 on opposite sidewalls of the fin structures 112 in the Y-direction are removed, as shown in FIGS. 6B and 6D. In these embodiments, the height of the gate spacers 124 on opposite sidewalls of the fin structures 112 in the Y-direction are reduced.

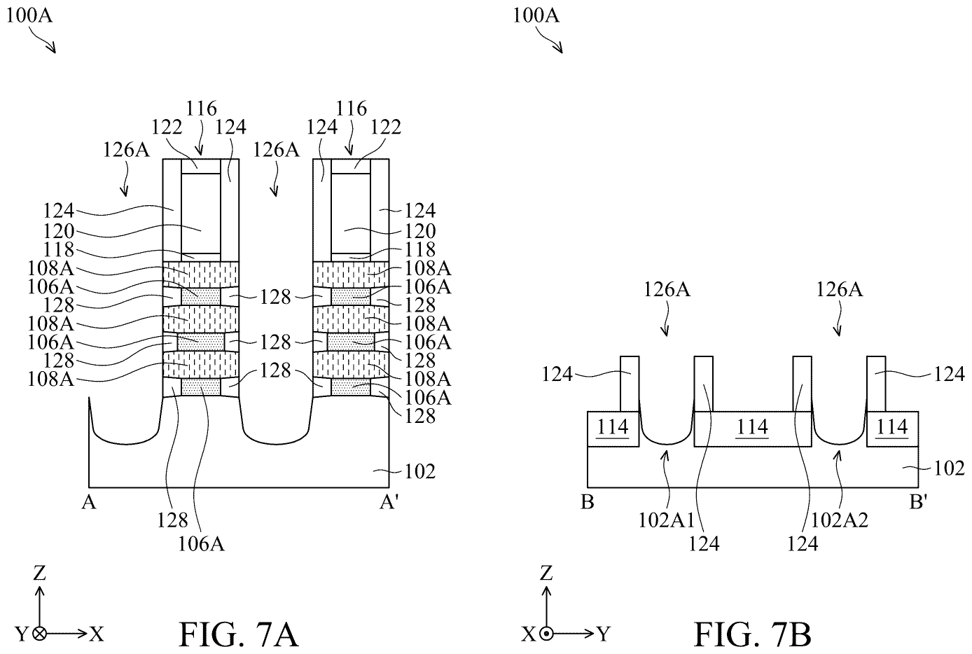

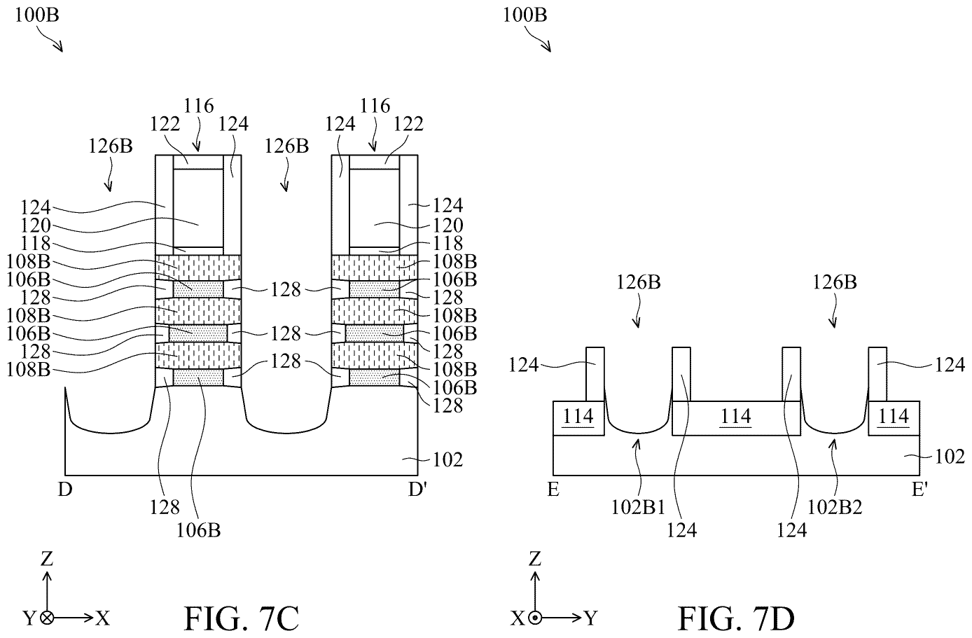

Referring to FIGS. 7A to 7D, the inner spacers 128 are formed between the semiconductor layers 108 (including the semiconductor layers 108A and 108B) as well as between the semiconductor layer 108 and the substrate 102, in accordance with some embodiments. FIGS. 7A and 7B are cross-sectional views of the semiconductor structure 100A along lines A-A′ and B-B′ of FIG. 4A, respectively. FIGS. 7C and 7D are cross-sectional views of the semiconductor structure 100B along lines D-D′ and E-E′ of FIG. 4B, respectively.

In some embodiments, the semiconductor layers 106A and 106B exposed in the source/drain trenches 126A and the semiconductor layers 106B exposed in the source/drain trenches 126B are partially recessed through a selective etching process, and the semiconductor layers 108A and 108B are not etched. More specifically, the selective etching process is performed that selectively etches the side portions of the semiconductor layers 106A and 106B below the gate spacers 124 through the source/drain trenches 126A and 126B, with minimal etching (or substantially no etching) of the semiconductor layers 108A and 108B and the substrate 102. After the selective etching process, inner spacer recesses are vertically formed between the semiconductor layers 108 (including the semiconductor layers 108A and 108B) as well as between the semiconductor layers 108 and the substrate 102, below the gate spacers 124. The selective etching process may be a dry etching process, a wet etching process, other suitable etching process, or a combination thereof.

Next, in some embodiments, a spacer layer is conformally formed into the source/drain trenches 126A and 126B and the inner spacer recesses. More specifically, a deposition process is performed to form the spacer layer into the source/drain trenches 126A and 126B and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (alternatively, completely) fills the source/drain trenches 126A and 126B and fully fills the inner spacer recesses. The deposition process is configured to ensure that the spacer layer fills the inner spacer recesses. Furthermore, the spacer layer is also conformally formed on the gate spacers 124 and the isolation structures 114.

The spacer layer may include a material that is different than the materials of the semiconductor layers 108 and the gate spacers 124 to achieve desired etching selectivity during the etching process. In some embodiments, the spacer layer include a dielectric material that includes silicon, oxygen, carbon, nitrogen, other suitable material, or combinations thereof (e.g., SiO₂, SiON, SiOC, SiCN, SiOCN). In some embodiments, the spacer layer include a low-k dielectric material, such as those described herein.

Then, in some embodiments, the inner spacers 128 are formed to fill the inner spacer recesses between the semiconductor layers 108 (including the semiconductor layers 108A and 108B) as well as between the semiconductor layer 108 and the substrate 102. More specifically, an etching process is performed to selectively etch the spacer layer to form the inner spacers 128 with minimal etching (or substantially no etching) of the semiconductor layers 108, the substrate 102, the dummy gate structures 116, and the gate spacers 124. The etching process may be an anisotropic etching process, removing the portions of the spacer layer that the dummy gate structures 116 and gate spacers 124 do not cover or vertically overlap. The spacer layer on the gate spacers 124 and the isolation structures 114 are removed.

In some embodiments, sidewalls of the inner spacers 128 are aligned to the sidewalls of the gate spacers 124 and the semiconductor layers 108A or 108B. Therefore, the inner spacers 128 are formed on opposite sides of the dummy gate structure 116. In some embodiments, in the semiconductor structure 100A, the inner spacers 128 are also vertically between the semiconductor layers 108A as well as between the semiconductor layer 108A and the substrate 102. Similarly, in the semiconductor structure 100B, the inner spacers 128 are also vertically between the semiconductor layers 108B as well as between the semiconductor layer 108B and the substrate 102. In other embodiments, sidewalls of the inner spacers 128 have concave surfaces exposed by the source/drain trenches 126A or 126B. In some embodiments, sidewalls of the inner spacers 128 in contact with the semiconductor layers 106A or 106B have convex surfaces.

In some embodiments, the thicknesses of the inner spacers 128 in the X-direction are different. For example, the thickness of the second topmost inner spacer 128 is less than that of the other inner spacers 128. That is, the pairs of inner spacers 128 that are formed on opposite sides of the second topmost semiconductor layers 106A and on opposite sides of the second topmost semiconductor layers 106B in the X-direction are thinner than other inner spacers 128, as shown in FIGS. 7A and 7C. In other words, the second topmost semiconductor layer 106A is longer than the other semiconductor layers 106A in the X-direction, and the second topmost semiconductor layer 106B is longer than the other semiconductor layers 106B in the X-direction.

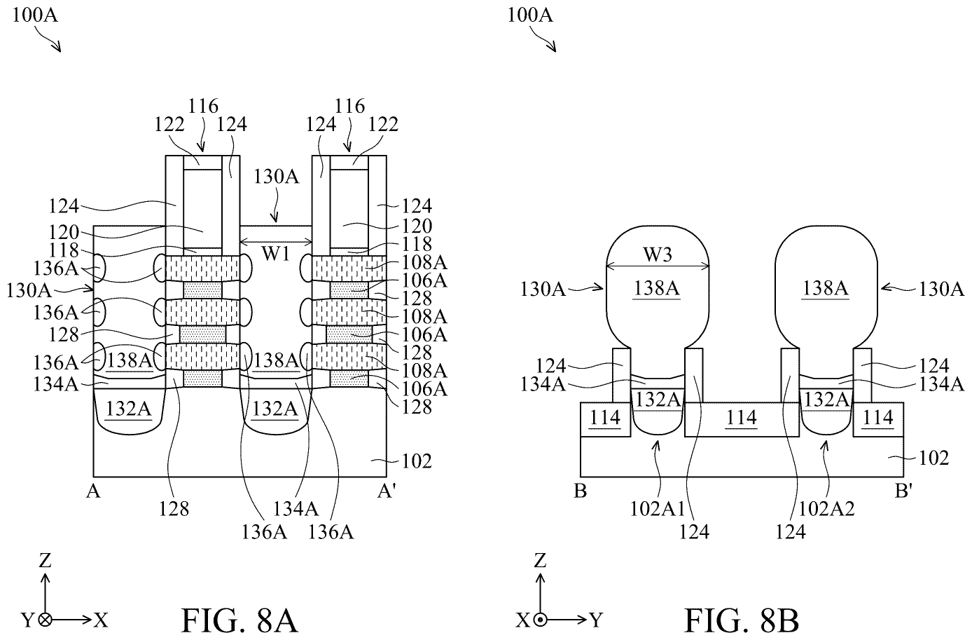

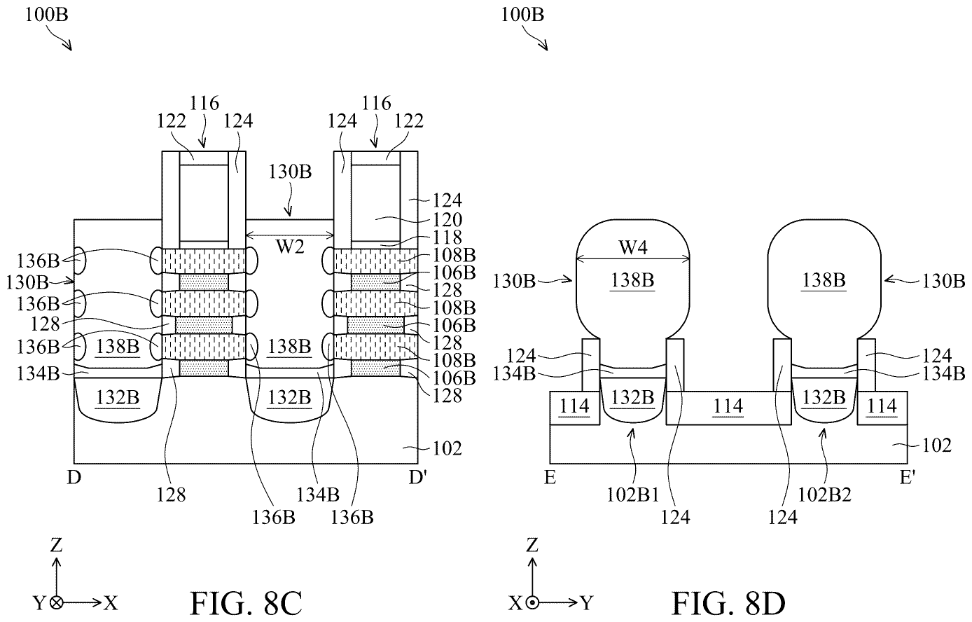

Referring to FIGS. 8A to 8D, source/drain features 130A and 130B are formed in the source/drain trenches 126A and 126B, respectively, in accordance with some embodiments. FIGS. 8A and 8B are cross-sectional views of the semiconductor structure 100A along lines A-A′ and B-B′ of FIG. 4A, respectively. FIGS. 8C and 8D are cross-sectional views of the semiconductor structure 100B along lines D-D′ and E-E′ of FIG. 4B, respectively.

In some embodiments, the first epitaxial layers 132A and 132B are formed on the bottoms of the source/drain trenches 126A and 126B, respectively, such that the first epitaxial layers 132A and 132B extend into and are in direct contact with the substrate 102 in the Z-direction. In some embodiments, the first epitaxial layers 132A and 132B are substantially free of dopants. The first epitaxial layers 132A and 132B may include Si, Ge, SiGe, another suitable semiconductor material, or a combination thereof. In some embodiments, the first epitaxial layers 132A and 132B include silicon that is substantially free of n-type dopants and p-type dopants. In some embodiments, the first epitaxial layers 132A and 132B are epitaxially grown using an epitaxial growth process such as VPE, MOCVD, MBE, although other deposition processes, such as CVD, LPCVD, PECVD, ALD, UHVCVD, RPCVD, combinations thereof, or the like, may also be utilized.

In some embodiments, the bottom isolation layers 134A and 134B are formed on the first epitaxial layers 132A and 132B, respectively. In some embodiments, each of the bottom isolation layers 134A and 134B includes end portions that have greater thickness than a middle portion between the end portions. The end portions may be in contact with the bottommost inner spacers 128. In some embodiments, the top surfaces of the bottom isolation layers 134A and 134B are lower than the bottom surfaces of the bottommost semiconductor layers 108A and 108B, respectively. In some embodiments, the top surfaces of the bottom isolation layers 134A and 134B are above the topmost surfaces of the substrate 102.

In some embodiments, the bottom isolation layers 134A and 134B may be a single dielectric layer or a multiple dielectric layers structure. In some embodiments, the dielectric material of the bottom isolation layers 134A and 134B may include Si₃N₄, SiO₂, SiC, SiOC, SiON, SiCN, SiOCN, high-k dielectrics, other suitable materials, or combinations thereof. In some embodiments, the bottom isolation layers 134A and 134B may be deposited by CVD, PVD, ALD, HDPCVD, MOCVD, RPCVD, PECVD, LPCVD, ALCVD, APCVD, other suitable methods, or combinations thereof.

In some embodiments, the first epitaxial layers 132A and 132B are omitted. In these embodiments, the bottom isolation layers 134A and 134B are formed on the bottoms of the source/drain trenches 126A and 126B, respectively, such that the bottom isolation layers 134A and 134B extend into and are in direct contact with the substrate 102 in the Z-direction.

In some embodiments, second epitaxial layers 136A and third epitaxial layers 138A are formed in the source/drain trenches 126A and over the bottom isolation layers 134A. More specifically, the second epitaxial layers 136A are formed from the end portions of the semiconductor layers 108A, and the third epitaxial layers 138A are formed from the second epitaxial layers 136A. In some embodiments, second epitaxial layers 136B and third epitaxial layers 138B are formed in the source/drain trenches 126B and over the bottom isolation layers 134B. More specifically, the second epitaxial layers 136B are formed from the end portions of the semiconductor layers 108B, and the third epitaxial layers 138B are formed from the second epitaxial layers 136B.

In some embodiments, the second epitaxial layers 136A and 136B (which may collectively be referred to as second epitaxial layers 136) are in a discontinuous form. That is, the second epitaxial layers 136 are separated and the second epitaxial layers 136 do not physically contact or merge together. In some embodiments, the second epitaxial layers 136 may have a height that is about the same as or greater than the thickness of the adjacent semiconductor layers 108. In some embodiments, the second epitaxial layers 136 may have a shape that is similar to a segment of a circle, a segment of an ellipse, a triangle, or another shape. In some embodiments, the third epitaxial layers 138A and 138B may have top surfaces that extend higher than the top surfaces of the topmost semiconductor layers 108A and 108B (e.g., in the Z-direction).

In other embodiments, second epitaxial layers 136 are in a form of continuous layer. The second epitaxial layers 136 may extend continuously along sidewalls of the source/drain trenches 126A or 126B. For example, the second epitaxial layers 136 may cover sidewalls of the semiconductor layers 108 within the source/drain trenches 126A or 126B and cover sidewalls of the inner spacers 128 between the semiconductor layers 108. The second epitaxial layer 136 may extend continuously along surfaces from a sidewall of the semiconductor layer 108 that is closest to the substrate 102 to a sidewall of the semiconductor layer 108 that is farthest from the substrate 102.

After the formation of the third epitaxial layers 138A and 138B, source/drain features 130A and 130B are formed. In some embodiments, each of the source/drain features 130A includes the first epitaxial layer 132A, the bottom isolation layer 134A, the second epitaxial layers 136A, and the third epitaxial layer 138A. Similarly, in some embodiments, each of the source/drain features 130B includes the first epitaxial layer 132B, the bottom isolation layer 134B, the second epitaxial layers 136B, and the third epitaxial layer 138B. The source/drain features 130A and 130B may also be referred to as source/drain, or source/drain regions. In some embodiments, source/drain feature(s) may refer to a source or a drain, individually or collectively dependent upon the context.

In some embodiments, in the semiconductor structure 100A, the source/drain features 130A are formed in the source/drain trenches 126A, and formed on opposite sides of the dummy gate structures 116 in the X-direction. In some embodiments, the source/drain features 130A are attached to and are electrically connected to opposite sides of the semiconductor layers 108A. In further embodiments, the semiconductor layers 108A serve as channels to connect one source/drain feature 130A to another source/drain feature 130A. In some embodiments, in the semiconductor structure 100B, the source/drain features 130B are formed in the source/drain trenches 126B, and formed on opposite sides of the dummy gate structures 116 in the X-direction. In some embodiments, the source/drain features 130B are attached to and are electrically connected to opposite sides of the semiconductor layers 108B. In further embodiments, the semiconductor layers 108B serve as channels to connect one source/drain feature 130B to another source/drain feature 130B. The semiconductor layers 108A and 108B may also be referred to as channels, channel layers, or channel members.

In some embodiments, since the devices formed from the semiconductor structure 100A has smaller CPP and the devices formed from the semiconductor structure 100B has larger CPP, the devices formed from the semiconductor structure 100B have more space to allocate to source/drain regions. Therefore, the source/drain features 130B in the semiconductor structure 100B may have greater widths than the source/drain features 130A in the semiconductor structure 100A. For example, the width W2 of the source/drain features 130B in the X-direction is greater than the width W1 of the source/drain features 130A in the X-direction, as shown in FIGS. 8A and 8C. In some embodiments, the width W2 is greater than the width W1 by a range from about 1 nm to about 40 nm, such as by a range from about 1 nm to about 10 nm. For example, the width W4 of the source/drain features 130B in the Y-direction is greater than the width W3 of the source/drain features 130A in the Y-direction, as shown in FIGS. 8B and 8D. In some embodiments, the width W4 is greater than the width W3 by a range from about 5 nm to about 100 nm, such as by a range from about 5 nm to about 40 nm.

In some embodiments, the second epitaxial layers 136A and 136B and the third epitaxial layers 138A and 138B include the same semiconductor material but with different constituent concentrations. The semiconductor material may include silicon, germanium, silicon germanium, other suitable semiconductor material, or combinations thereof. In some embodiments, the source/drain features 130A may be p-type source/drain features or n-type source/drain features, and the source/drain features 130B may be p-type source/drain features or n-type source/drain features.

For the p-type source/drain features, the second epitaxial layers 136A and 136B and the third epitaxial layers 138A and 138B include p-doped silicon germanium but with different p-type concentrations. For example, the second epitaxial layers 136A and 136B may have a p-type dopant concentration of about 1×10²⁰/cm³ to about 5×10²⁰/cm³, and the third epitaxial layers 138A and 138B may have a p-type dopant concentration of about 5×10²⁰/cm³ to about 2×10²¹/cm³. For the n-type source/drain features, the second epitaxial layers 136A and 136B and the third epitaxial layers 138A and 138B include n-doped silicon but with different n-type concentrations. For example, the second epitaxial layers 136A and 136B may have an n-type dopant concentration of about 1×10²⁰/cm³ to about 5×10²⁰/cm³, and the third epitaxial layers 138A and 138B may have an n-type dopant concentration of about 5×10²⁰/cm³ to about 2×10²¹/cm³.

In some embodiments, the second epitaxial layers 136A and 136B are epitaxially grown from the semiconductor layers 108A and 108B using an epitaxial growth process. In some embodiments, the third epitaxial layers 138A and 138B are epitaxially grown from the second epitaxial layers 136A and 136B using an epitaxial growth process. The epitaxial growth processes for forming the second epitaxial layers 136A and 136B and the third epitaxial layers 138A and 138B may be VPE, MOCVD, MBE, or other deposition processes, such as CVD, LPCVD, PECVD, ALD, UHVCVD, RPCVD, combinations thereof, or the like. In some embodiments, the second epitaxial layers 136A and 136B and the third epitaxial layers 138A and 138B are doped in-situ or ex-situ. In some embodiments, one or more annealing processes may be performed to activate the dopants in the second epitaxial layers 136A and 136B and the third epitaxial layers 138A and 138B. The annealing processes may include rapid thermal annealing (RTA) and/or laser annealing processes.

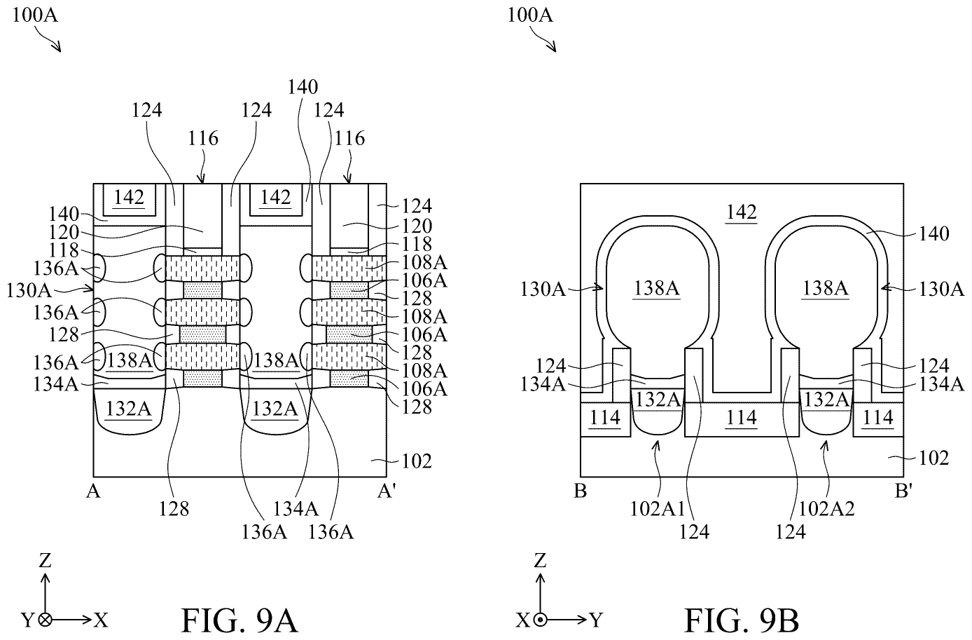

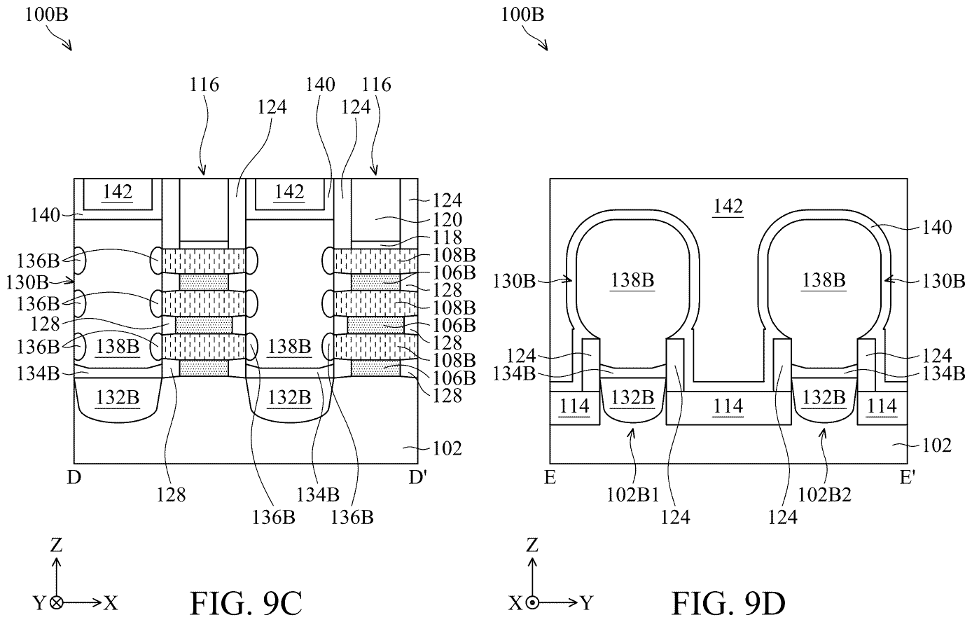

Referring to FIGS. 9A to 9D, contact etch stop layers (CESLs) 140 are formed over the source/drain features 130A and 130B, and interlayer dielectric (ILD) layers 142 are formed over the CESLs 140, in accordance with some embodiments. FIGS. 9A and 9B are cross-sectional views of the semiconductor structure 100A along lines A-A′ and B-B′ of FIG. 4A, respectively. FIGS. 9C and 9D are cross-sectional views of the semiconductor structure 100B along lines D-D′ and E-E′ of FIG. 4B, respectively.

In some embodiments, the CESLs 140 are conformally formed on sidewalls of the gate spacers 124, on surfaces of the source/drain features 130A and 130B, and over top surfaces of the isolation structures 114, as shown in FIGS. 9A to 9D. The ILD layers 142 are formed over and between the CESLs 140 to fill the spaces between the CESLs 140 or between the gate spacers 124.

The CESLs 140 may include a material that is different than ILD layers 142. The CESLs 140 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AION, TaCN, ZrSi, or other suitable materials. The CESLs 140 may be formed by CVD, PVD, ALD, HDPCVD, MOCVD, RPCVD, PECVD, LPCVD, ALCVD, APCVD, FCVD, or other suitable methods. The ILD layers 142 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), a low-k dielectric material, another suitable dielectric material, or a combination thereof. The ILD layers 142 may be formed by CVD, PVD, ALD, HDPCVD, MOCVD, RPCVD, PECVD, LPCVD, ALCVD, APCVD, FCVD, or other suitable methods.

Subsequent to the deposition of the CESLs 140 and the ILD layers 142, a CMP process and/or some other planarization process is performed on the CESLs 140, the ILD layers 142, the gate spacers 124, and the hard masks layers 122 until the top surfaces of the dummy gate electrode layers 120 are exposed. In some embodiments, portions of the dummy gate electrode layers 120 are removed after the planarization process.

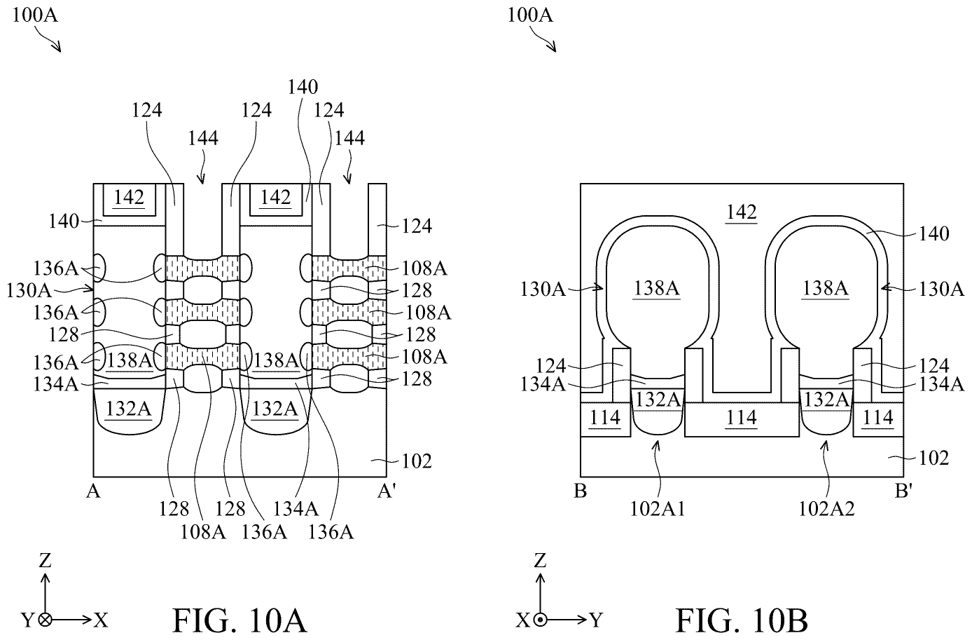

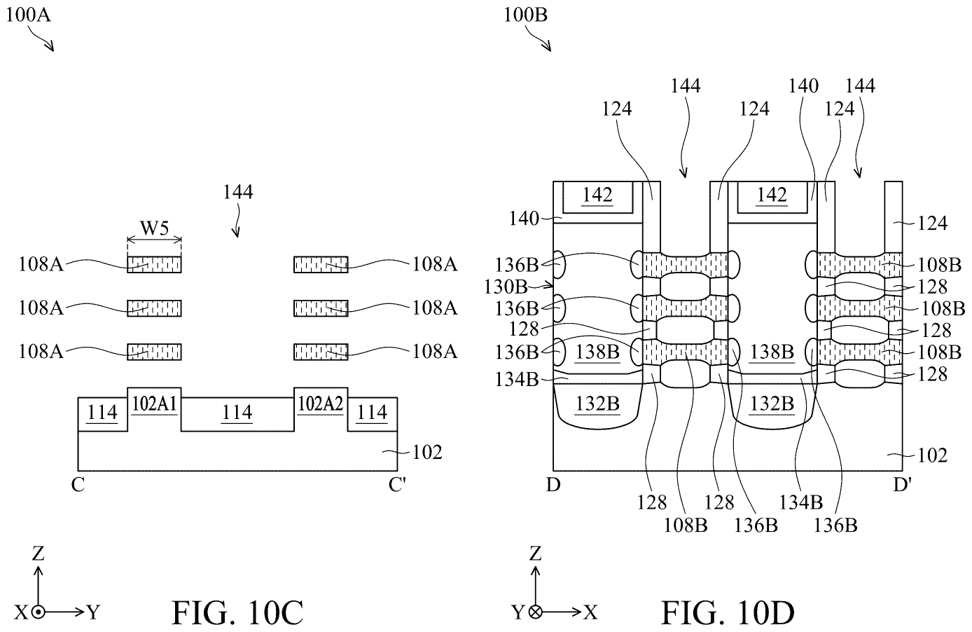

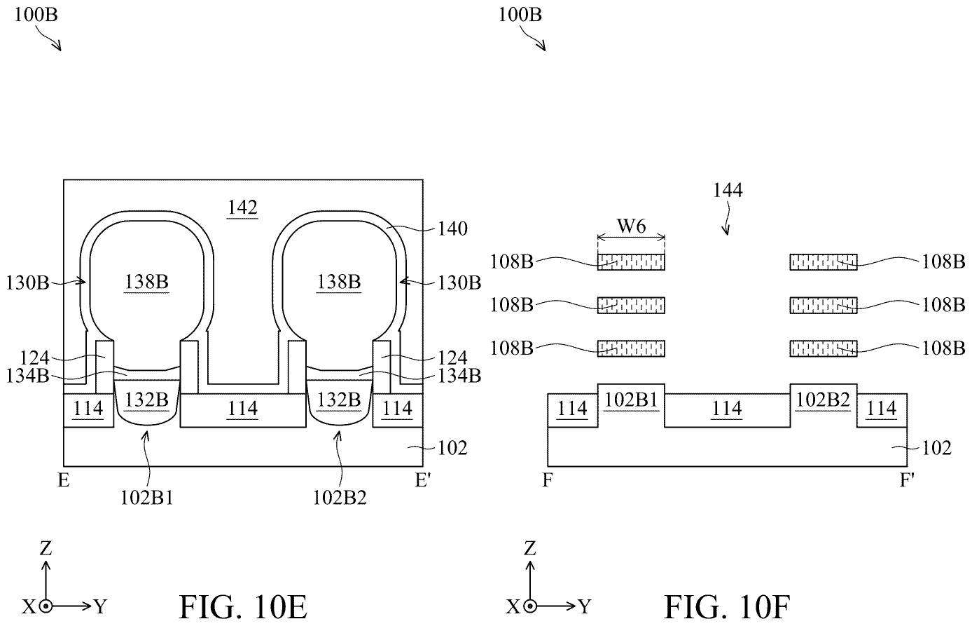

Referring to FIGS. 10A to 10F, the dummy gate structures 116 are selectively removed through any suitable photolithography and etching processes, in accordance with some embodiments. FIGS. 10A, 10B, and 10C are cross-sectional views of the semiconductor structure 100A along lines A-A′, B-B′, and C-C′ of FIG. 4A, respectively. FIGS. 10D, 10E, and 10F are cross-sectional views of the semiconductor structure 100B along lines D-D′, E-E′, and F-F′ of FIG. 4B, respectively.

In some embodiments, the photolithography process may include forming a photoresist layer, exposing the resist to a pattern, performing a post-exposure bake process, and developing the photoresist to form a masking element, which exposes a region including the dummy gate structures 116. Then, the dummy gate structures 116 are selectively etched through the masking element. The gate spacers 124 may be used as the masking element or a part thereof. Etch selectivity may be achieved by selecting appropriate etching chemicals, and the dummy gate structures 116 may be removed without substantially affecting the CESLs 140 and the ILD layers 142. The removal of the dummy gate structures 116 creates gate trenches 144, as shown in FIGS. 10A, 10C, 10D, and 10F. The gate trenches 144 may expose the top surfaces of the topmost semiconductor layers 108A and 108B that underlie the dummy gate structures 116.

Still referring to FIGS. 10A to 10F, the semiconductor layers 106A and 106B are selectively removed through the gate trenches 144, using a wet or dry etching process for example, in accordance with some embodiments. After the semiconductor layers 106A and 106B are selectively removed, the semiconductor layers 108A and 108B are exposed in the gate trenches 144 to form the nanostructures stacked on top of each other. As such, the semiconductor layers 108A and 108B may be referred to as nanostructures. Such a process may also be referred to as a wire/nanowire/nanosheet release process, or a wire/nanowire/nanosheet formation process.

In some embodiments, the active region in the semiconductor structure 100B may have greater widths than the active region in the semiconductor structure 100A. That is, the semiconductor layers 108B may have greater widths than the semiconductor layers 108A in the Y-direction. For example, the width W6 of the semiconductor layers 108B in the Y-direction is greater than the width W5 of the semiconductor layers 108A in the Y-direction, as shown in FIGS. 10C and 10F. In some embodiments, the width W6 is greater than the width W5 by a range from about 5 nm to about 100 nm, such as by a range from about 5 nm to about 40 nm.

In some embodiments, the semiconductor layers 108A are stacked over and spaced apart from each other in the Z-direction, and the semiconductor layers 108B are stacked over and spaced apart from each other in the Z-direction. More specifically, the semiconductor layers 108A are suspended over, and vertically arranged over, the substrate 102 in the Z-direction and constitute vertical stacks, and the semiconductor layers 108B are suspended over, and vertically arranged over, the substrate 102 in the Z-direction and constitute vertical stacks.

In some embodiments, portions of the semiconductor layers 108 exposed in the gate trenches 144 may be partially etched during the removal of the semiconductor layers 106. For example, each of the semiconductor layers 108A and 108B may include end portions covered by the inner spacers 128 and the gate spacers 124, and include a middle portion between the end portions and exposed by the gate trench 144. The middle portions exposed in the gate trenches 144 may be partially etched during the removal of the semiconductor layers 106A and 106B, so that the end portions have greater thickness than the middle portion. For example, after the removal of the semiconductor layers 106A and 106B, each of the semiconductor layers 108A and 108B may have a dumbbell shape (or dog-bone shape), as shown in FIGS. 10A and 10D.

In some embodiments, thicknesses of the inner spacers 128 exposed in the gate trenches 144 in X-direction may be reduced during the removal of the semiconductor layers 106A and 106B. In some embodiments, after the removal of the semiconductor layers 106A and 106B, the thicknesses of the inner spacers 128 in the X-direction may be different. For example, in one stack of the inner spacers 128 directly under one gate spacer 124, the thickness of the second topmost inner spacer 128 are less than other inner spacers 128. That is, the pairs of inner spacers 128 formed between the second and third topmost semiconductor layers 108A and between the second and third topmost semiconductor layers 108B in the Z-direction are thinner than the other inner spacers 128.

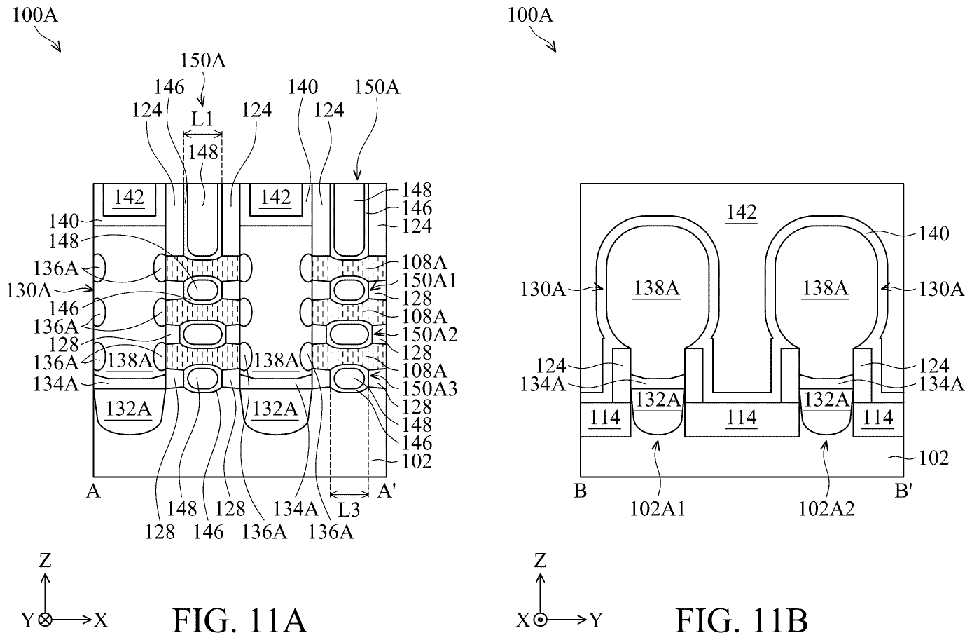

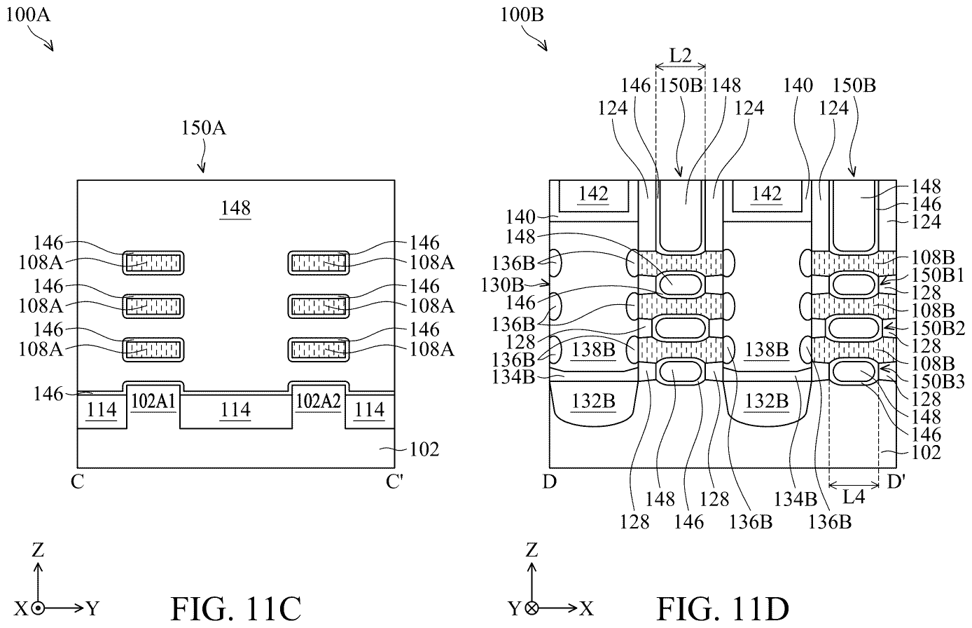

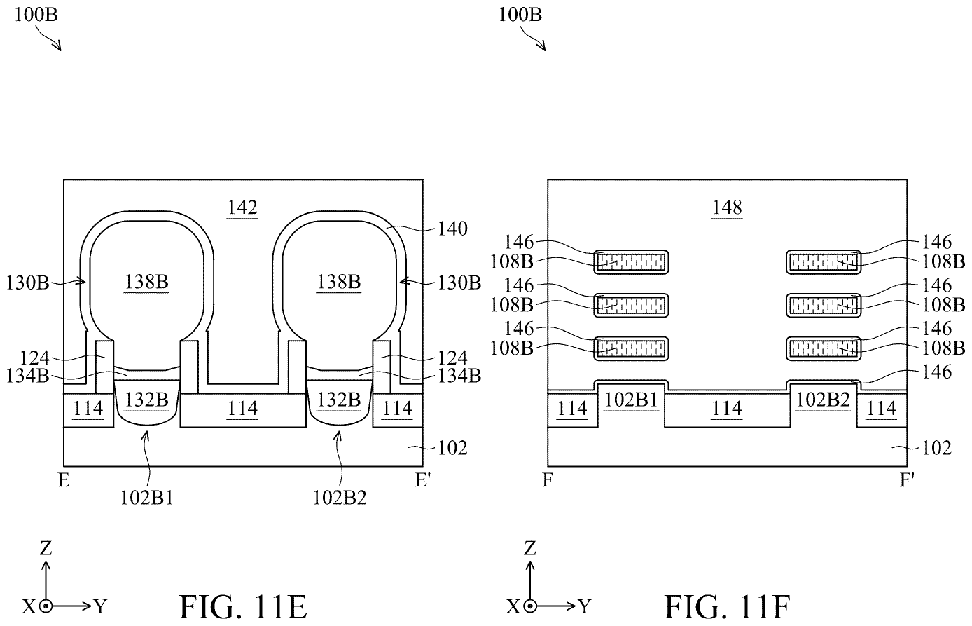

Referring to FIGS. 11A to 11F, gate structures 150A and 150B are formed in the gate trenches 144 to wrap around each of the exposed semiconductor layers 108A and 108B, respectively, in accordance with some embodiments. As such, the gate structures 150A and 150B replace the dummy gate structures 116. FIGS. 11A, 11B, and 11C are cross-sectional views of the semiconductor structure 100A along lines A-A′, B-B′, and C-C′ of FIG. 4A, respectively. FIGS. 11D, 11E, and 11F are cross-sectional views of the semiconductor structure 100B along lines D-D′, E-E′, and F-F′ of FIG. 4B, respectively.

In some embodiments, the gate structures 150A and 150B extend in the Y-direction. In some embodiments, the source/drain features 130A are formed on opposite sides of the gate structures 150A in the X-direction, as shown in FIG. 11A. In some embodiments, the source/drain features 130B are formed on opposite sides of the gate structures 150B in the X-direction, as shown in FIG. 11D. In some embodiments, the gate structures 150A and 150B each includes a gate dielectric layer 146 and a gate electrode layer 148 over the gate dielectric layer 146. In some embodiments, the gate dielectric layers 146 are formed to wrap around semiconductor layers 108A and 108B in the gate trenches 144. In some embodiments, the gate dielectric layers 146 are also formed on the sidewalls of the inner spacers 128 and the gate spacers 124, and over the top surfaces of the isolation structure 114 and the base fins 102A1, 102A2, 102B1, and 102B2.

In some embodiments, the gate dielectric layers 146 may include a dielectric material, such as SiOCN, SiOC, SiCN, SiO₂, SiN, SiC, or other suitable materials. In some embodiments, the gate dielectric layers 146 may include a high-k dielectric material that has a dielectric constant greater than a dielectric constant of SiO₂, which is approximately 3.9. For example, the gate dielectric layers 146 may include hafnium oxide (HfO₂), which has a dielectric constant in a range from about 18 to about 40. Alternatively, the gate dielectric layers 146 may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, SiON, combinations thereof, or other suitable materials. The gate dielectric layers 146 may be formed by CVD, PVD, ALD, HDPCVD, MOCVD, RPCVD, PECVD, LPCVD, ALCVD, APCVD, FCVD, oxidation, and/or other suitable methods.

In some embodiments, each of the gate structures 150A and 150B may further include an interfacial layer (not shown) that is formed to wrap around the exposed semiconductor layers 108A and 108B before the formation of the gate dielectric layers 146, so that the gate dielectric layers 146 are separated from the semiconductor layers 108A and 108B by the interfacial layers. In some embodiments, the interfacial layer may include a dielectric material such as SiO₂, HfSiO, or SiON. The interfacial layer may be formed by chemical oxidation, thermal oxidation, CVD, PVD, ALD, HDPCVD, MOCVD, RPCVD, PECVD, LPCVD, ALCVD, APCVD, FCVD, and/or other suitable method.

The gate electrode layers 148 are formed to fill the remaining spaces of the gate trenches 144, and over the gate dielectric layers 146 in such a way that the gate electrode layers 148 wrap around the semiconductor layers 108A and 108B, the gate dielectric layer 146, and the interfacial layers (if present). The gate electrode layers 148 each may include a single layer or a multi-layer structure. In some embodiments, the gate electrode layers 148 each may include a capping layer, a barrier layer, work function metal layers, and a fill material. The gate electrode layers 148 may be formed using a deposition process such as CVD, PVD, ALD, HDPCVD, MOCVD, RPCVD, PECVD, LPCVD, ALCVD, APCVD, FCVD, or the like, although any suitable deposition process may be used.

In some embodiments, the capping layer and the barrier layer may include different materials, and may be formed of metallic materials such as TaN, Ti, TiAIN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

For p-type FETs (PFETs), the gate electrode layers may include p-type work function metal layers. For n-type FETs (NFETs), the gate electrode layers may include n-type work function metal layers. The n-type and p-type work function metal layers may include conductive materials tuned to have a desired work function (e.g., an n-type work function or a p-type work function). In some embodiments, the n-type and p-type work function metal layers may include a material such as W, Al, Cu, TiN, Ti, TiAIN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

Still referring to FIGS. 11A to 11F, the gate structures 150A and 150B may each be divided into an outer gate structure and an inner gate structure, in accordance with some embodiments. For example, each of the gate structures 150A has an outer gate structure that is over, and an inner gate structure that is under, the top surface of the topmost semiconductor layer 108A. For example, each of the gate structures 150B has an outer gate structure that is over, and an inner gate structure that is under, the top surface of the topmost semiconductor layer 108B.

In some embodiments, since the devices formed from the semiconductor structure 100A has smaller CPP and the devices formed from the semiconductor structure 100B has larger CPP, the devices formed from the semiconductor structure 100B have more space to allocate to channel regions and gate structures. Therefore, the gate structures 150B in the semiconductor structure 100B may have greater widths than the gate structures 150A in the semiconductor structure 100A. For example, in the X-direction, the length L2 of the outer gate structures of the gate structures 150B is greater than the length L1 of the outer gate structures of the gate structures 150A, as shown in FIGS. 11A and 11D. In some embodiments, the length L2 is greater than the length L1 by a range from about 1 nm to about 40 nm, such as by a range from about 1 nm to about 4 nm. For example, in the X-direction, the length L4 of the inner gate structures of the gate structures 150B is greater than the length L3 of the inner gate structures of the gate structures 150A, as shown in FIGS. 11A and 11D. In some embodiments, the length L4 is greater than the length L3 by a range from about 1 nm to about 40 nm, such as by a range from about 1 nm to about 4 nm. In some embodiments, since the length L2 is greater than the length L1 and/or the length L4 is greater than the length L3, the lengths of the semiconductor layers 108B are greater than the lengths of the semiconductor layers 108A in the X-direction.

In some embodiments, for each of the gate structures 150A in semiconductor structure 100A, the inner gate structure includes a first inner portion 150A1 between the topmost and second topmost semiconductor layers 108A, a second inner portion 150A2 between the second and third topmost semiconductor layers 108A, and a third inner portion 150A3 between the third topmost semiconductor layer 108A and the substrate 102. In some embodiments, since the pairs of inner spacers 128 formed between the second and third topmost semiconductor layers 108A are thinner than the other inner spacers 128 in the X-direction, the length of the second inner portion 150A2 is greater than the lengths of the first inner portion 150A1 and the third inner portion 150A3 in the X-direction, as shown in FIG. 11A.

In some embodiments, for each of the gate structures 150B in semiconductor structure 100B, the inner gate structure includes a first inner portion 150B1 between the topmost and second topmost semiconductor layers 108B, a second inner portion 150B2 between the second and third topmost semiconductor layers 108B, and a third inner portion 150B3 between the third topmost semiconductor layer 108B and the substrate 102. In some embodiments, since the pairs of inner spacers 128 formed between the second and third topmost semiconductor layers 108B are thinner than the other inner spacers 128 in the X-direction, the length of the second inner portion 150B2 is greater than the lengths of the first inner portion 150B1 and the third inner portion 150B3 in the X-direction, as shown in FIG. 11D.

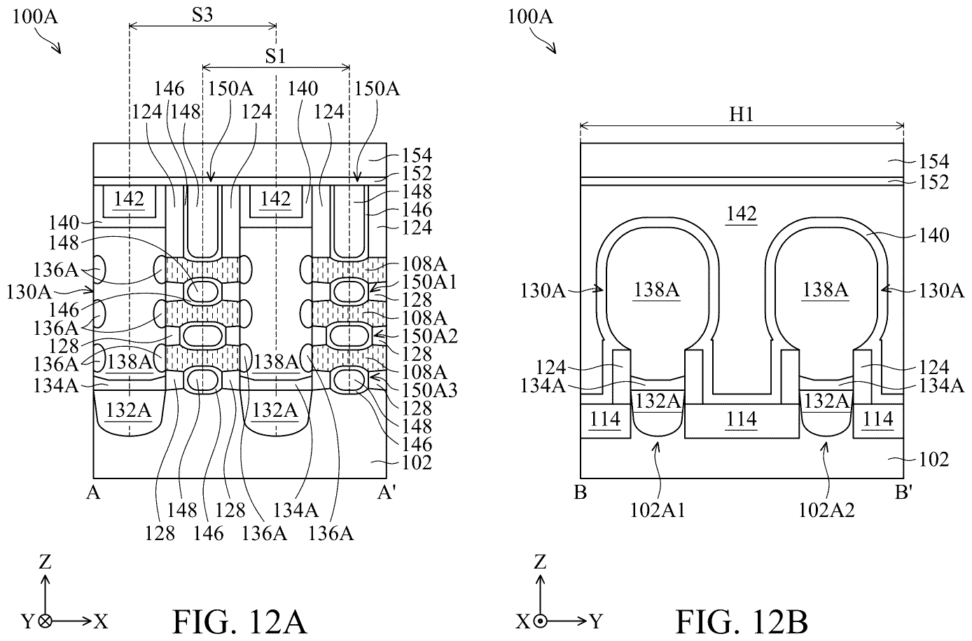

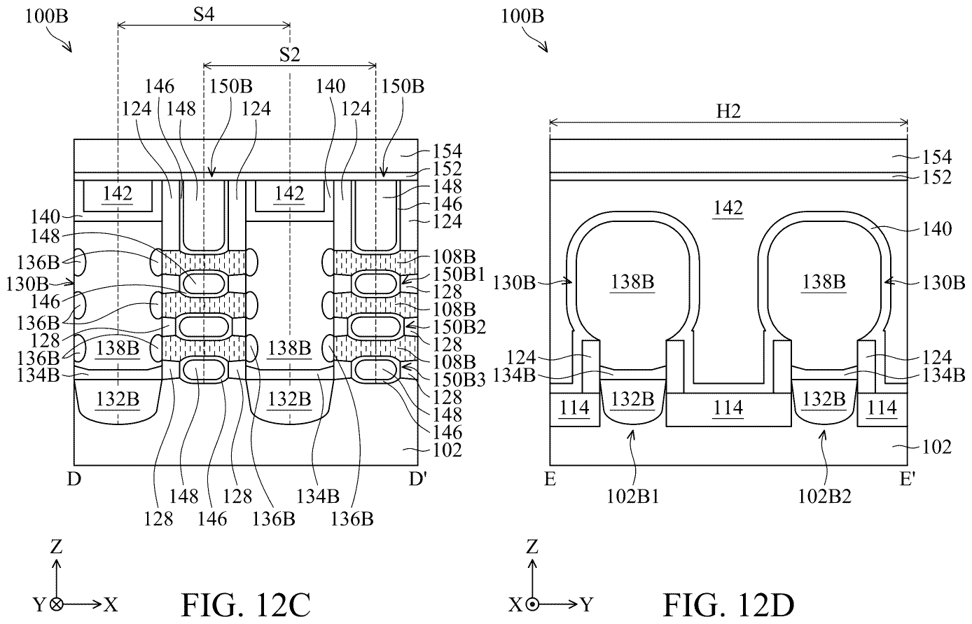

Referring to FIGS. 12A to 12D, etch stop layers (ESLs) 152 and ILD layers 154 are formed over the semiconductor structures 100A and 100B, in accordance with some embodiments. FIGS. 12A and 12B are cross-sectional views of the semiconductor structure 100A along lines A-A′ and B-B′ of FIG. 4A, respectively. FIGS. 12C and 12D are cross-sectional views of the semiconductor structure 100B along lines D-D′ and E-E′ of FIG. 4B, respectively.

In some embodiments, the ESLs 152 are formed on the gate spacers 124, the CESLs 140, the ILD layers 142, and the gate structures 150A and 150B, and the ILD layers 154 are formed on the ESLs 152, as shown in FIGS. 12A to 12D. In some embodiments, the material and method used in forming the ESLs 152 and the ILD layers 154 are the same as or similar to those of the CESLs 140 and the ILD layers 142, respectively, and are not repeated herein.

In some embodiments, the semiconductor structure 100A has a distance S1 between the middle line of one gate structure 150A and the middle line of the adjacent gate structure 150A in the X-direction, as shown in FIG. 12A. In some embodiments, the semiconductor structure 100B has a distance S2 between the middle line of one gate structure 150B and the middle line of the adjacent gate structure 150B in the X-direction, as shown in FIG. 12C. As described above, in some embodiments, the devices formed from the semiconductor structure 100A has smaller CPP and the devices formed from the semiconductor structure 100B has larger CPP. Therefore, the distance S1 of the semiconductor structure 100A is smaller than the distance S2 of the semiconductor structure 100B. In some embodiments, the distance S2 is greater than the distance S1 by a range from about 1 nm to 40 nm, such as by a range from about 2 nm to about 20 nm. In some embodiments, the distance S1 corresponds to the CPP of the semiconductor structure 100A, and the distance S2 corresponds to the CPP of the semiconductor structure 100B.

In other embodiments, the CPP may be defined by the distance between one source/drain feature and the adjacent source/drain feature. In some embodiments, the semiconductor structure 100A has a distance S3 between the middle line of one source/drain feature 130A and the middle line of the adjacent source/drain feature 130A in the X-direction, as shown in FIG. 12A. In some embodiments, the semiconductor structure 100B has a distance S4 between the middle line of one source/drain feature 130B and the middle line of the adjacent source/drain feature 130B in the X-direction, as shown in FIG. 12C. In some embodiments, the distance S3 of the semiconductor structure 100A is smaller than the distance S4 of the semiconductor structure 100B. In some embodiments, the distance S4 is greater than the distance S3 by a range from about 1 nm to 40 nm, such as by a range from about 2 nm to about 20 nm.

In some embodiments, the semiconductor structures 100A and 100B may be formed into cells (e.g., memory cells or standard cells). In some embodiments, the cells formed from the semiconductor structures 100A and 100B may each includes two fin structures 112 arranged in the Y-direction, so that the cells may each includes two source/drain features (e.g., the source/drain features 130A or 130B) of two transistors arranged in the Y-direction. In some embodiments, the cells formed from the semiconductor structures 100A have a cell height H1 in the Y-direction, as shown in FIG. 12B, and the cells formed from the semiconductor structures 100B have a cell height H2 in the Y-direction, as shown in FIG. 12D. In some embodiments, the cell height H2 is greater than the cell height H1 by a range from about 10 nm to about 200 nm, such as by a range from about 10 nm to about 100 nm.

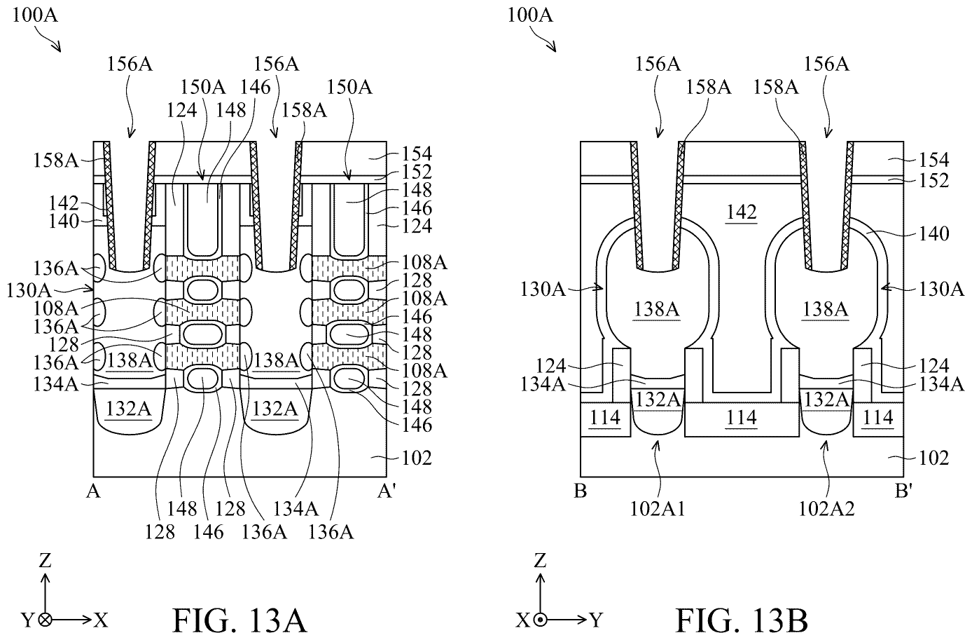

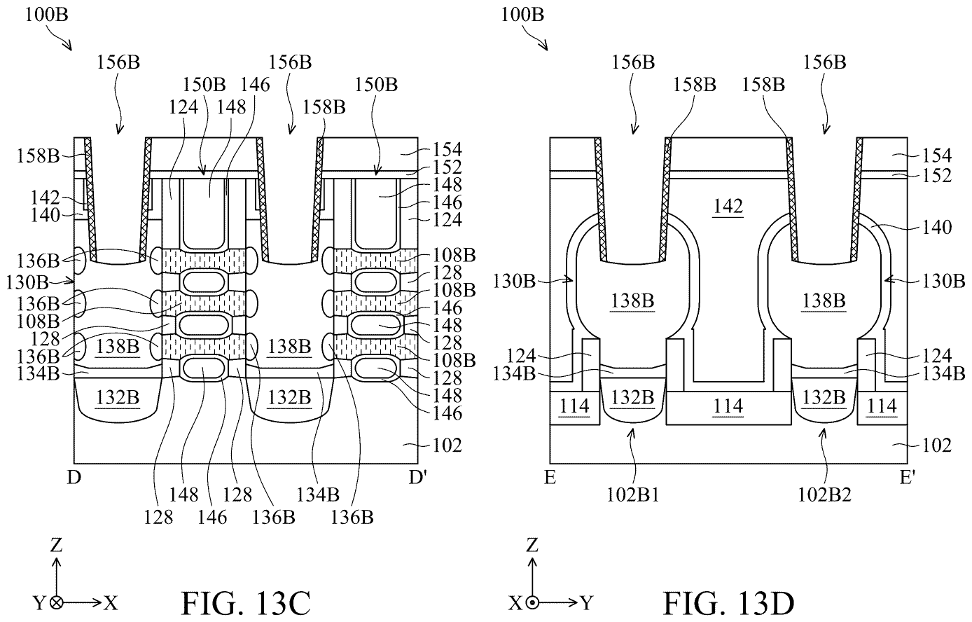

Referring to FIGS. 13A to 13D, trenches for accommodating source/drain contacts are formed to expose the source/drain features 130A and 130B, in accordance with some embodiments. FIGS. 13A and 13B are cross-sectional views of the semiconductor structure 100A along lines A-A′ and B-B′ of FIG. 4A, respectively. FIGS. 13C and 13D are cross-sectional views of the semiconductor structure 100B along lines D-D′ and E-E′ of FIG. 4B, respectively.

In some embodiments, in the semiconductor structure 100A, trenches 156A are formed to pass through the ILD layers 154, the ESLs 152, the ILD layers 142, the CESLs 140, and portions of the source/drain features 130A, so as to expose the source/drain features 130A. In further embodiments, the trenches 156A extend in the third epitaxial layers 138A of the source/drain features 130A without contacting the second epitaxial layers 136A, as shown in FIG. 13A. In some embodiments, the bottom portions of the trenches 156A have an arc shape, and thus the surfaces of the third epitaxial layers 138A of the source/drain features 130A exposed by the trenches 156A also have an arc shape, as shown in FIGS. 13A and 13B.

In some embodiments, in the semiconductor structure 100B, trenches 156B are formed to pass through the ILD layers 154, the ESLs 152, the ILD layers 142, the CESLs 140, and portions of the source/drain features 130B, so as to expose the source/drain features 130B. In further embodiments, the trenches 156B extend in the third epitaxial layers 138B of the source/drain features 130B without contacting the second epitaxial layers 136B, as shown in FIG. 13C. In some embodiments, the bottom portions of the trenches 156B have an arc shape, and thus the surfaces of the third epitaxial layers 138B of the source/drain features 130B exposed by the trenches 156B also have an arc shape, as shown in FIGS. 13C and 13D.

In some embodiments, one or more photolithography and etching processes are performed to etch the ILD layers 154, the ESLs 152, the ILD layers 142, and the CESLs 140, and partially etch the source/drain features 130A and 130B, so as to form the trenches 156A that expose the source/drain features 130A and form the trenches 156B that expose the source/drain features 130B. In further embodiments, the third epitaxial layers 138A of the source/drain features 130A and the third epitaxial layers 138B of the source/drain features 130B are partially etched, so that the trenches 156A and the trenches 156B expose the third epitaxial layers 138A and the third epitaxial layers 138B, respectively.

As described above, in some embodiments, the devices formed from the semiconductor structure 100A have smaller CPP and the devices formed from the semiconductor structure 100B have larger CPP. Therefore, the trenches 156B in the semiconductor structure 100B may be formed greater than the trenches 156A in the semiconductor structure 100A. In some embodiments, the width of the trenches 156B is greater than the width of the trenches 156A in the X-direction, as shown in FIGS. 13A and 13C. In some embodiments, the width of the trenches 156B is greater than the width of the trenches 156A in the Y-direction, as shown in FIGS. 13B and 13D.

Still referring to FIGS. 13A to 13D, sidewall dielectric layers 158A and 158B are formed on sidewalls of the trenches 156A and 156B, respectively, in accordance with some embodiments. In other words, the sidewall dielectric layers 158A are formed on surfaces of the ILD layers 154, the ESLs 152, the ILD layers 142, the CESLs 140, and the third epitaxial layers 138A that form the sidewalls of the trenches 156A, while bottoms of the trenches 156A still expose the third epitaxial layers 138A. Similarly, the sidewall dielectric layers 158B are formed on surfaces of the ILD layers 154, the ESLs 152, the ILD layers 142, the CESLs 140, and the third epitaxial layers 138B that form the sidewalls of the trenches 156B, while bottoms of the trenches 156B still expose the third epitaxial layers 138B. In some embodiments, the material of the sidewall dielectric layer 158A and 158B may include Si₃N₄, SiO₂, SiC, SiOC, SiON, SiCN, SiOCN, high-k dielectrics, other suitable materials, or combinations thereof.

In some embodiments, the sidewall dielectric layers 158A and 158B may be formed by conformally depositing a material layer (containing dielectric material) on the surfaces of the ILD layers 154 and the trenches 156A and 156B. An anisotropic etching process is then performed to remove horizontal portions of the material layer from the top surfaces of the ILD layers 154 and the bottom surfaces of the trenches 156A and 156B. After the anisotropic etching process, the portions of the material layer on the sidewall surfaces of the trenches 156A and 156B remain and become the sidewall dielectric layers 158A and 158B, and the horizontal surfaces of the third epitaxial layers 138A and 138B are still exposed by the trenches 156A and 156B, respectively. In some embodiments, the anisotropic etching process is a dry (e.g., plasma) etching process. Additionally or alternatively, the formation of the sidewall dielectric layers 158A and 158B may also involve chemical oxidation, thermal oxidation, CVD, PVD, ALD, HDPCVD, MOCVD, RPCVD, PECVD, LPCVD, ALCVD, APCVD, FCVD, and/or other suitable methods.

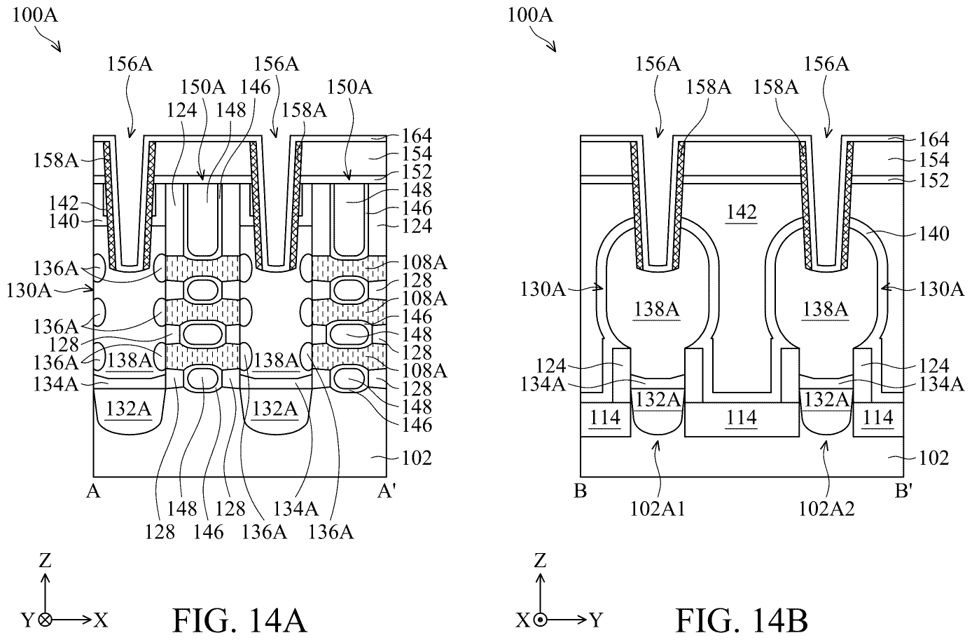

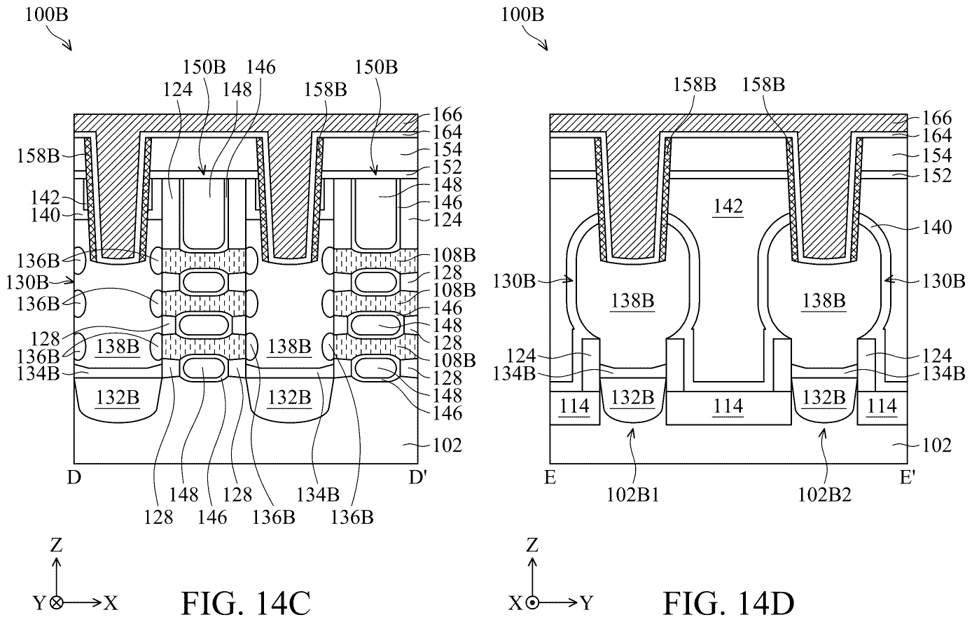

Referring to FIGS. 14A to 14D, a hard mask layer 164 is formed on the semiconductor structures 100A and 100B, in accordance with some embodiments. FIGS. 14A and 14B are cross-sectional views of the semiconductor structure 100A along lines A-A′ and B-B′ of FIG. 4A, respectively. FIGS. 14C and 14D are cross-sectional views of the semiconductor structure 100B along lines D-D′ and E-E′ of FIG. 4B, respectively.

In some embodiments, in the semiconductor structure 100A, the hard mask layer 164 is conformally formed on the top surface of the ILD layers 154 and the sidewalls and the bottom surfaces of the trenches 156A. That is, the top surface of the ILD layers 154, the top surfaces and the sidewalls of the sidewall dielectric layers 158A, and the surfaces of the third epitaxial layers 138A exposed by the trenches 156A are covered by the hard mask layer 164, as shown in FIGS. 14A and 14B. In some embodiments, in the semiconductor structure 100B, the hard mask layer 164 is conformally formed on the top surface of the ILD layers 154 and the sidewalls and the bottom surfaces of the trenches 156B. That is, the top surface of the ILD layers 154, the top surfaces and the sidewalls of the sidewall dielectric layers 158B, and the surfaces of the third epitaxial layers 138B exposed by the trenches 156B are covered by the hard mask layer 164, as shown in FIGS. 14C and 14D.

In some embodiments, the material of the hard mask layer 164 may include Si₃N₄, SiON, SiCN, SiOCN, high-k dielectrics, another suitable material, or a combinations thereof. In some embodiments, the hard mask layer 164 may be formed by CVD, PVD, ALD, HDPCVD, MOCVD, RPCVD, PECVD, LPCVD, ALCVD, APCVD, FCVD, or other suitable methods.

Still referring to FIGS. 14A to 14D, a patterned photoresist layer 166 is formed on the semiconductor structure 100B, in accordance with some embodiments. In some embodiments, the patterned photoresist layer 166 is formed in the region 101B without being formed in the region 101A, so as to cover the semiconductor structure 100B and expose the semiconductor structure 100A. Specifically, the patterned photoresist layer 166 covers a second portion of the hard mask layer 164 formed in the semiconductor structure 100B. In some embodiments, the patterned photoresist layer 166 fills the remaining spaces of the trenches 156B, as shown in FIGS. 14C and 14D. In some embodiments, the patterned photoresist layer 166 is formed by a photolithography process that includes forming a photoresist layer, exposing the photoresist layer to a pattern, performing a post-exposure bake process, and developing the photoresist layer to form the patterned photoresist layer 166, which covers the semiconductor structure 100B and exposes the semiconductor structure 100A.

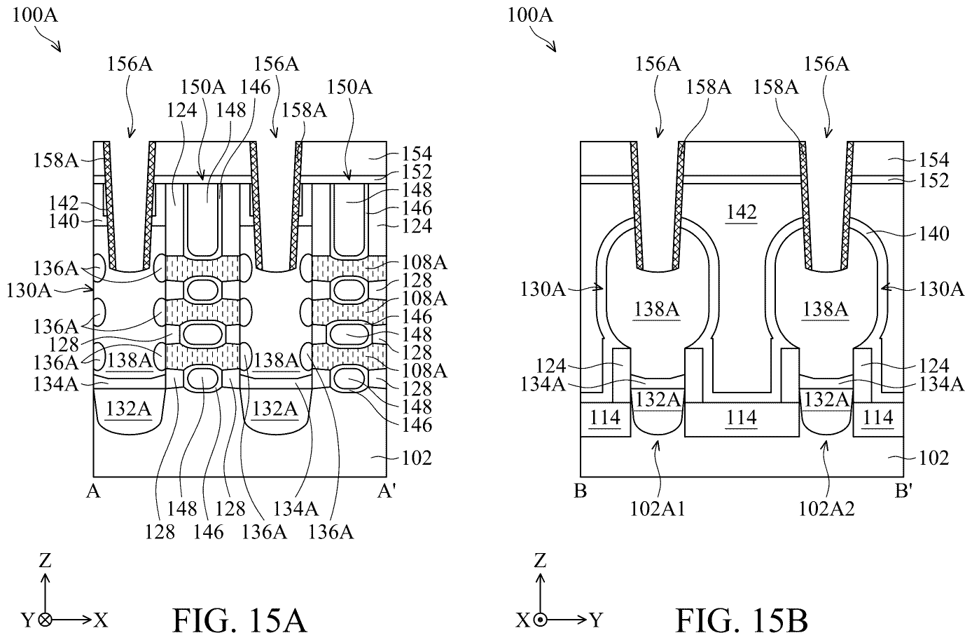

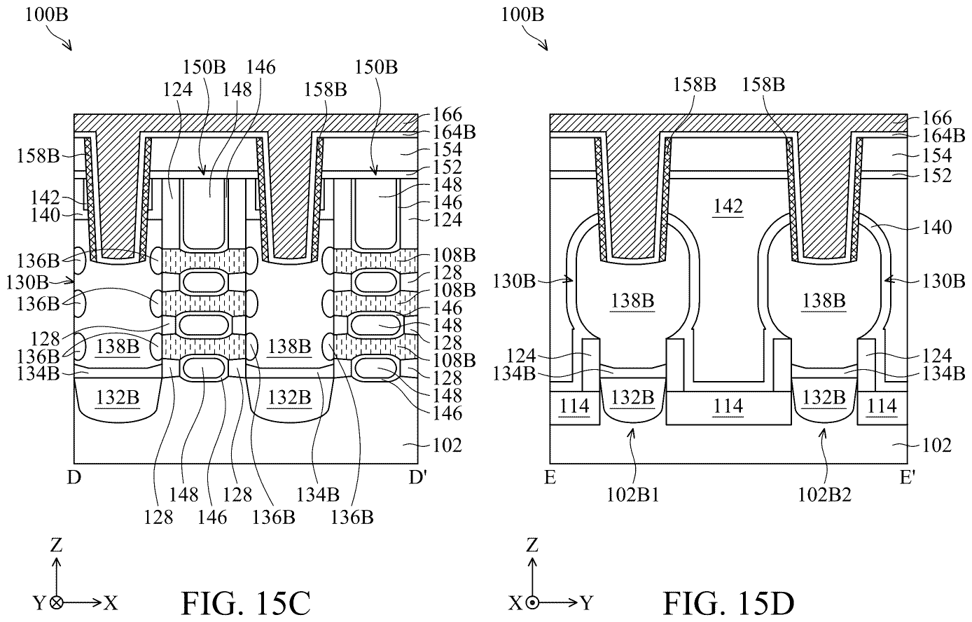

Referring to FIGS. 15A to 15D, a first portion of hard mask layer 164 formed in semiconductor structure 100A is removed, in accordance with some embodiments. FIGS. 15A and 15B are cross-sectional views of the semiconductor structure 100A along lines A-A′ and B-B′ of FIG. 4A, respectively. FIGS. 15C and 15D are cross-sectional views of the semiconductor structure 100B along lines D-D′ and E-E′ of FIG. 4B, respectively.

In some embodiments, the first portion of the hard mask layer 164 formed in the semiconductor structure 100A is removed by one or more etching processes. The etching processes may be selective etching processes that selectively etch the hard mask layer 164, with minimal etching (or substantially no etching) of the ILD layers 154, the sidewall dielectric layers 158A, and the third epitaxial layers 138A. The selective etching process may be a dry etching process, a wet etching process, other suitable etching process, or combinations thereof. In some embodiments, due to being covered by the patterned photoresist layer 166, the second portion of the hard mask layer 164 formed in the semiconductor structure 100B is protected from the etching processes and remains after the etching processes.

In some embodiments, after the etching processes, the first portion of the hard mask layer 164 formed in the semiconductor structure 100A is removed, and the second portion of the hard mask layer 164 formed in the semiconductor structure 100B remains and becomes a hard mask layer 164B. As such, the semiconductor structure 100B is still covered by the hard mask layer 164B (and the patterned photoresist layer 166), while the semiconductor structure 100A is not covered by the hard mask layer 164, as shown in FIGS. 15A to 15D. After the etching processes, the surfaces of the third epitaxial layers 138A are exposed by the trenches 156A, as shown in FIGS. 15C and 15D.

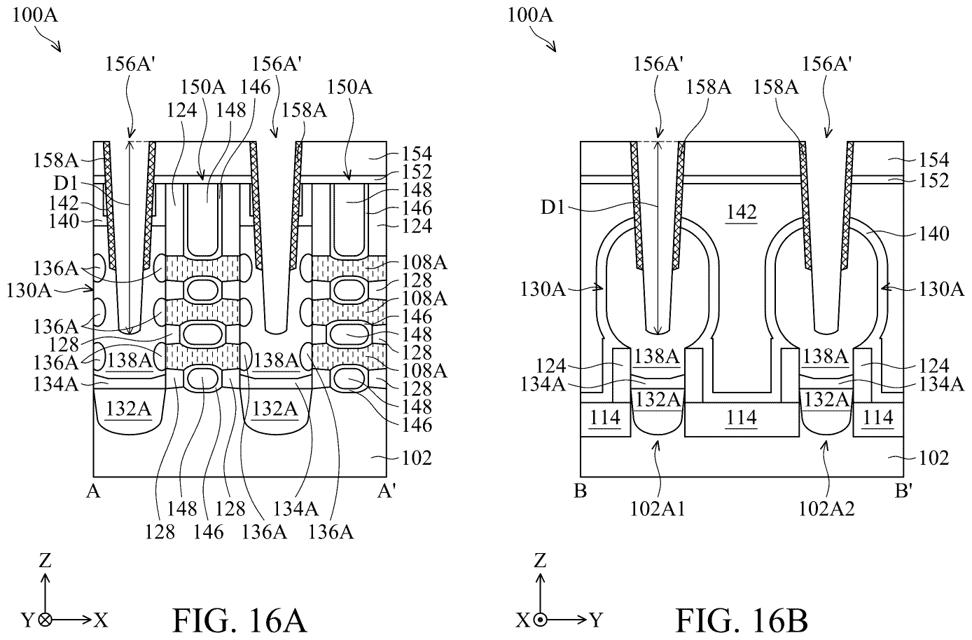

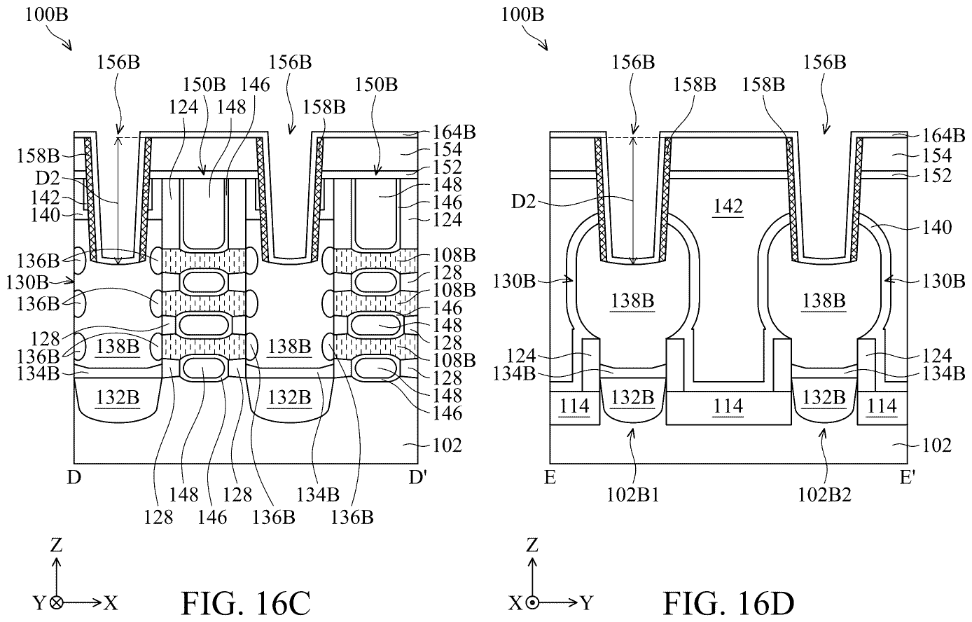

Referring to FIGS. 16A to 16D, the patterned photoresist layer 166 is removed and the trenches 156A are further extended, in accordance with some embodiments. FIGS. 16A and 16B are cross-sectional views of the semiconductor structure 100A along lines A-A′ and B-B′ of FIG. 4A, respectively. FIGS. 16C and 16D are cross-sectional views of the semiconductor structure 100B along lines D-D′ and E-E′ of FIG. 4B, respectively.

In some embodiments, the patterned photoresist layer 166 is removed from the semiconductor structure 100B, for example, using a photoresist ashing or stripping process. After removing the patterned photoresist layer 166, the semiconductor structure 100B is still covered by the hard mask layer 164B. More specifically, the trenches 156B are still covered by the hard mask layer 164B, such that the surfaces of the third epitaxial layers 138B exposed by the trenches 156B are still covered by the hard mask layer 164B.

Still referring to FIGS. 16A to 16D, the third epitaxial layers 138A are partially etched to further extend the trenches 156A downward in the Z-direction, in accordance with some embodiments. After etching, the extended trenches 156A can be referred to as trenches 156A′, which have depths that are greater than depths of the trenches 156A in the Z-direction. In some embodiments, the trenches 156A are extended by one or more etching processes. The etching processes may be selective etching processes that selectively etch the third epitaxial layers 138A, with minimal etching (or substantially no etching) of the ILD layers 154, the sidewall dielectric layers 158A, and the hard mask layer 164B. The selective etching process may be a dry etching process, a wet etching process, other suitable etching process, or combinations thereof. The selective etching process may also be an anisotropic etching process.

In some embodiments, due to being covered by the hard mask layer 164B, the elements in the semiconductor structure 100B, especially the third epitaxial layers 138B, are protected from the etching processes, such that the trenches 156B are not extended in the Z-direction during the etching processes. Therefore, in the Z-direction, the depth D2 of the trenches 156B keeps the same and is smaller than the depth D1 of the trenches 156A′, as shown in FIGS. 16A to 16D. In some embodiments, the depth D1 is greater than the depth D2 by a range from about 2 nm to about 25 nm. In some embodiments, the depth D2 is in a range from about 4 nm to about 40 nm.

In some embodiments, the trenches 156A′ extend downward into the height of the second topmost semiconductor layer 108A in the Z-direction. In certain embodiments, the trenches 156A′ extend downward into the height of the third topmost semiconductor layer 108A in the Z-direction. In some embodiments, the trenches 156B extend downward into the height of the topmost semiconductor layer 108B in the Z-direction. In other embodiments, each of the trenches 156A′ and 156B may have any suitable depth in the Z-direction.

In other embodiments, the patterned photoresist layer 166 is removed after extending the trenches 156A into the trenches 156A′. That is, the third epitaxial layers 138A are partially etched while both the hard mask layer 164B and the patterned photoresist layer 166 exist. In some embodiments, due to being covered by both the hard mask layer 164B and the patterned photoresist layer 166, the elements in the semiconductor structure 100B, especially the third epitaxial layers 138B, are protected from the etching processes, such that the trenches 156B are not extended in the Z-direction during the etching processes.

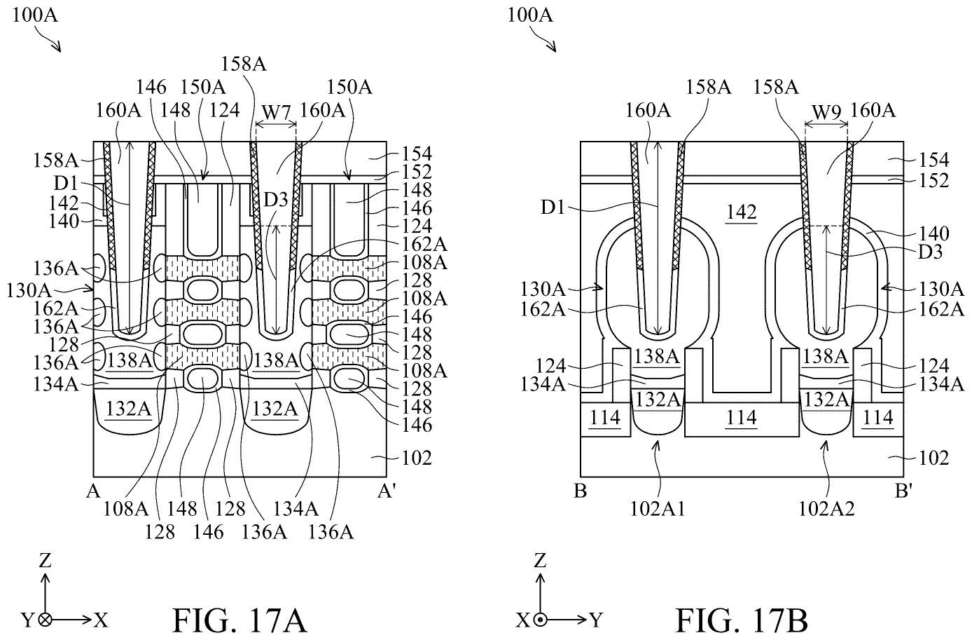

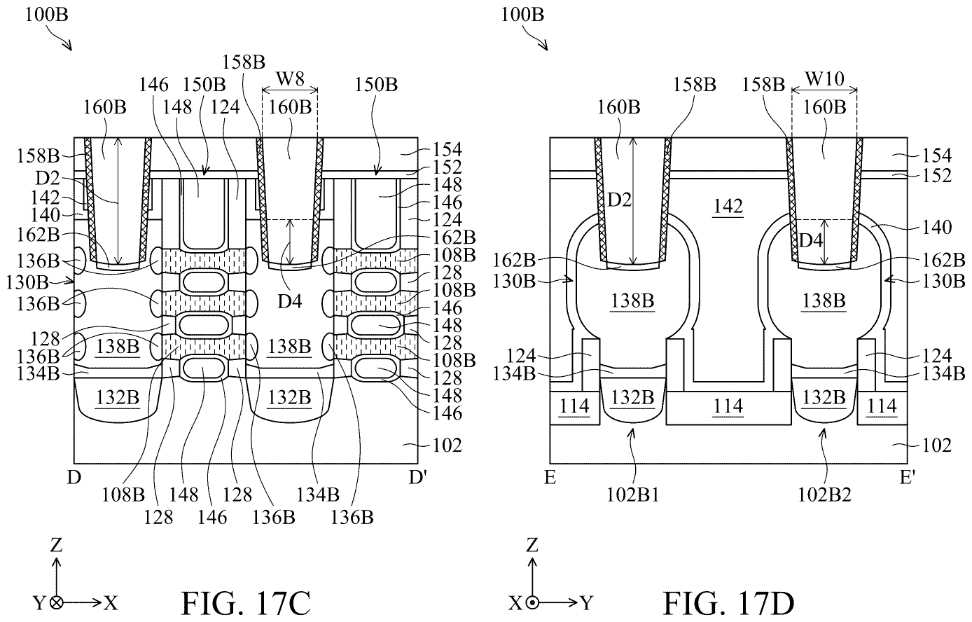

Referring to FIGS. 17A to 17D, the hard mask layer 164B is removed and the source/drain contacts are formed, in accordance with some embodiments. FIGS. 17A and 17B are cross-sectional views of the semiconductor structure 100A along lines A-A′ and B-B′ of FIG. 4A, respectively. FIGS. 17C and 17D are cross-sectional views of the semiconductor structure 100B along lines D-D′ and E-E′ of FIG. 4B, respectively.

In some embodiments, the hard mask layer 164B is removed by one or more etching processes. The etching processes may be selective etching processes that selectively etch the hard mask layer 164B, with minimal etching (or substantially no etching) of the ILD layers 154, the sidewall dielectric layers 158B, and the source/drain features 130B. The selective etching process may be a dry etching process, a wet etching process, other suitable etching process, or combinations thereof. In some embodiments, after the etching processes, the trenches 156B are exposed, and thus the third epitaxial layers 138B are exposed by the trenches 156B.

Still referring to FIGS. 17A to 17D, the silicide layers 162A are formed on the exposed surfaces of the third epitaxial layers 138A in the trenches 156A′, and the silicide layers 162B are formed on the exposed surfaces of the third epitaxial layers 138B in the trenches 156B, in accordance with some embodiments. In some embodiments, the silicide layers 162A are formed by depositing metal layers on the third epitaxial layers 138A, and heating the workpiece 100 to cause constituents of the third epitaxial layers 138A to react with metal constituents of the metal layers. Similarly, the silicide layers 162B may be formed by depositing metal layers on the third epitaxial layers 138B, and heating the workpiece 100 to cause constituents of the third epitaxial layers 138B to react with metal constituents of the metal layers. In some embodiments, the silicide layers 162A and 162B may include TiSi, NiSi, WSi, NiPtSi, NiPtGeSi, NiGeSi, YbSi, PtSi, IrSi, ErSi, CoSi, or other suitable compounds.

Still referring to FIGS. 17A to 17D, the source/drain contacts 160A and 160B are formed in the trenches 156A′ and 156B, respectively, in accordance with some embodiments. In some embodiments, a conductive material is deposited in the trenches 156A′ and 156B and on the silicide layers 162A and 162B by a deposition process, so as to form the source/drain contacts 160A and 160B. That is, the trenches 156A′ are filled with the conductive material to form the source/drain contacts 160A, and the trenches 156B are filled with the conductive material to form the source/drain contacts 160B. The conductive material may include Al, Cu, W, Co, Ti, Ta, Ru, Rh, Ir, Pt, TiN, TiAl, TiAlN, TaN, TaC, combinations thereof, or the like, although any suitable material may be used. The conductive material may be deposited using a deposition process such as sputtering, CVD, PVD, ALD, HDPCVD, MOCVD, RPCVD, PECVD, LPCVD, ALCVD, APCVD, FCVD, and/or other suitable method.

In some embodiments, the source/drain contacts 160A partially extend into and electrically connect to the source/drain features 130A of the semiconductor structure 100A. In further embodiments, the source/drain contacts 160A partially extend into the third epitaxial layers 138A of the source/drain features 130A without contacting the second epitaxial layers 136A, as shown in FIGS. 17A and 17B. In these embodiments, the source/drain contacts 160A are in contact with and electrically connected to the third epitaxial layers 138A, and are separated from the second epitaxial layers 136A by the third epitaxial layers 138A.

In some embodiments, the source/drain contacts 160B partially extend into and electrically connect to the source/drain features 130B of the semiconductor structure 100B. In further embodiments, the source/drain contacts 160B partially extend into the third epitaxial layers 138B of the source/drain features 130B without contacting the second epitaxial layers 136B, as shown in FIGS. 17C and 17D. In these embodiments, the source/drain contacts 160B are in contact with and electrically connected to the third epitaxial layers 138B, and are separated from the second epitaxial layers 136B by the third epitaxial layers 138B.

In some embodiments, the silicide layers 162A are formed on the bottoms and sidewalls of the lower portions of the source/drain contacts 160A, and formed between the source/drain contacts 160A and the source/drain features 130A (e.g., the third epitaxial layers 138A), such that the lower portions of the source/drain contacts 160A are surrounded by the silicide layers 162A, as shown in FIGS. 17A and 17B. In some embodiments, the silicide layers 162B are formed on the bottoms of the source/drain contacts 160B, and formed between the source/drain contacts 160B and the source/drain features 130B (e.g., the third epitaxial layers 138B), as shown in FIGS. 17C and 17D.

In some embodiments, since the bottom portions of the trenches 156A have an arc shape, the bottom surfaces of the silicide layers 162A include a curved profile. Similarly, in some embodiments, since the bottom portions of the trenches 156B have an arc shape, the silicide layers 162B include a curved profile. In some embodiments, a conductivity of the source/drain contacts 160A is greater than a conductivity of the source/drain features 130A and a conductivity of the silicide layers 162A. In some embodiments, a conductivity of the source/drain contacts 160B is greater than a conductivity of the source/drain features 130B and a conductivity of the silicide layers 162B.

In some embodiments, the sidewall dielectric layers 158A are formed on sidewalls of the upper portions of the source/drain contacts 160A, such that the upper portions of the source/drain contacts 160A are surrounded and separated from the ILD layers 154, the ESLs 152, the ILD layers 142, and the CESLs 140 by the sidewall dielectric layers 158A, as shown in FIGS. 17A and 17B. In some embodiments, the source/drain contacts 160A (including the sidewall dielectric layers 158A) are surrounded by the CESLs 140 and the ILD layers 142, and are spaced apart from the gate structures 150A by the CESLs 140, the ILD layers 142, and the gate spacers 124.

In some embodiments, the sidewall dielectric layers 158B are formed on sidewalls of the source/drain contacts 160B, such that the source/drain contacts 160B are surrounded and separated from the ILD layers 154, the ESLs 152, the ILD layers 142, and the CESLs 140 by the sidewall dielectric layers 158B, as shown in FIGS. 17C and 17D. In some embodiments, the source/drain contacts 160B (including the sidewall dielectric layers 158B) are surrounded by the CESLs 140 and the ILD layers 142, and are spaced apart from the gate structures 150B by the CESLs 140, the ILD layers 142, and the gate spacers 124.

In some embodiments, since the source/drain contacts 160A are formed in the trenches 156A′, the source/drain contacts 160A have the depths D1 that are the same as the trenches 156A′, as shown in FIGS. 17A and 17B. In some embodiments, since the source/drain contacts 160B are formed in the trenches 156B, the source/drain contacts 160B have the depths D2 that are the same as the trenches 156B, as shown in FIGS. 17C and 17D. As described above, in some embodiments, the depth D1 is greater than the depth D2 by a range from about 2 nm to about 25 nm. In some embodiments, the depth D2 is in a range from about 4 nm to about 40 nm. In some embodiments, the depths D3 that the source/drain contacts 160A extend inside the source/drain features 130A and the depths D4 that the source/drain contacts 160B extend inside the source/drain features 130B are in a range from about 4 nm to about 50 nm. In some embodiments, the depth D3 is greater than the depth D4 by a range from about 2 nm to about 25 nm.

In some embodiments, the bottom surfaces of the source/drain contacts 160A are lower than the top surfaces of the second topmost semiconductor layers 108A. In further embodiments, the bottom surfaces of the source/drain contacts 160A are lower than the bottom surfaces of the second topmost semiconductor layers 108A, as shown in FIG. 17A. In some embodiments, the bottom surfaces of the upper portions of the source/drain contacts 160A are higher than the top surfaces of the second topmost semiconductor layers 108A, and the bottom surfaces of the lower portions of the source/drain contacts 160A are lower than the bottom surfaces of the second topmost semiconductor layers 108A.

In some embodiments, the bottom surfaces of the source/drain contacts 160B are higher than the bottom surfaces of the second topmost semiconductor layers 108B. For example, the bottom surfaces of the source/drain contacts 160B may be higher than the top surfaces of the second topmost semiconductor layers 108B or higher than the top surfaces of the topmost semiconductor layers 108B. In certain embodiments, the bottom surfaces of the source/drain contacts 160B are between the top and bottom surfaces of the topmost semiconductor layers 108B, as shown in FIG. 17C.

In some embodiments, since the source/drain contacts 160A are deeper than the source/drain contacts 160B, the distance between the source/drain contacts 160A and the bottom isolation layers 134A is less than the distance between the source/drain contacts 160B and the bottom isolation layers 134B in the Z-direction, as shown in FIGS. 17A to 17D. In these embodiments, the distance between the source/drain contacts 160A and the substrate 102 is less than the distance between the source/drain contacts 160B and the substrate 102 in the Z-direction.

In some embodiments, since the devices formed from the semiconductor structure 100A has smaller CPP and the devices formed from the semiconductor structure 100B has larger CPP, the devices formed from the semiconductor structure 100B have more space to allocate to source/drain contacts. Therefore, the source/drain contacts 160B in the semiconductor structure 100B may have greater widths than the source/drain contacts 160A in the semiconductor structure 100A. For example, the width W8 of the source/drain contacts 160B in the X-direction is greater than the width W7 of the source/drain contacts 160A in the X-direction, as shown in FIGS. 17A and 17C. In some embodiments, the width W8 is greater than the width W7 by a range from about 1 nm to about 40 nm, such as by a range from about 1 nm to about 10 nm. In some embodiments, the width W7 is in a range from about 6 nm to about 40 nm. For example, the width W10 of the source/drain contacts 160B in the Y-direction is greater than the width W9 of the source/drain contacts 160A in the Y-direction, as shown in FIGS. 17B and 17D. In some embodiments, the width W10 is greater than the width W9 by a range from about 5 nm to about 100 nm, such as by a range from about 5 nm to about 40 nm.

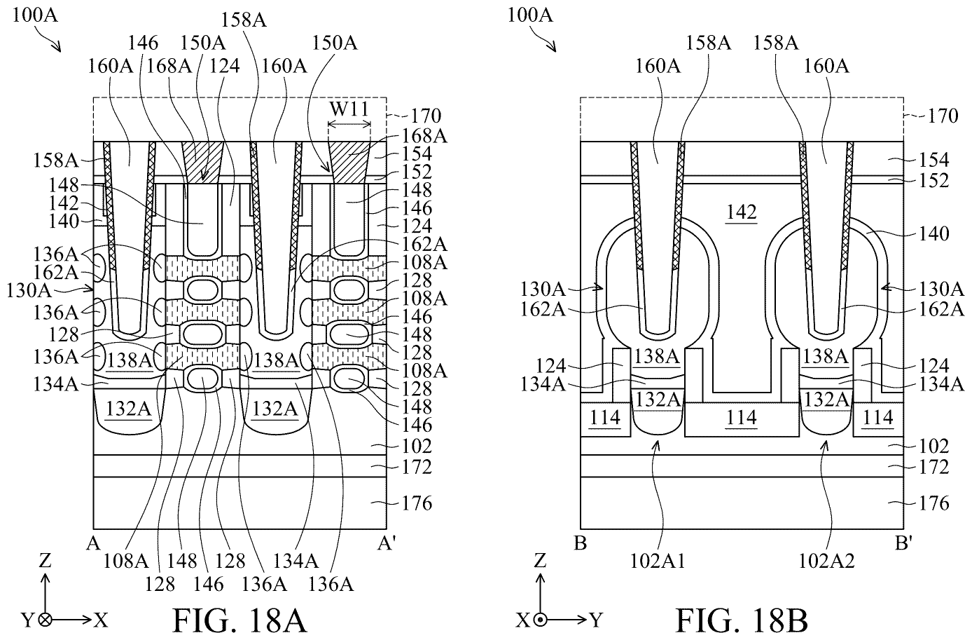

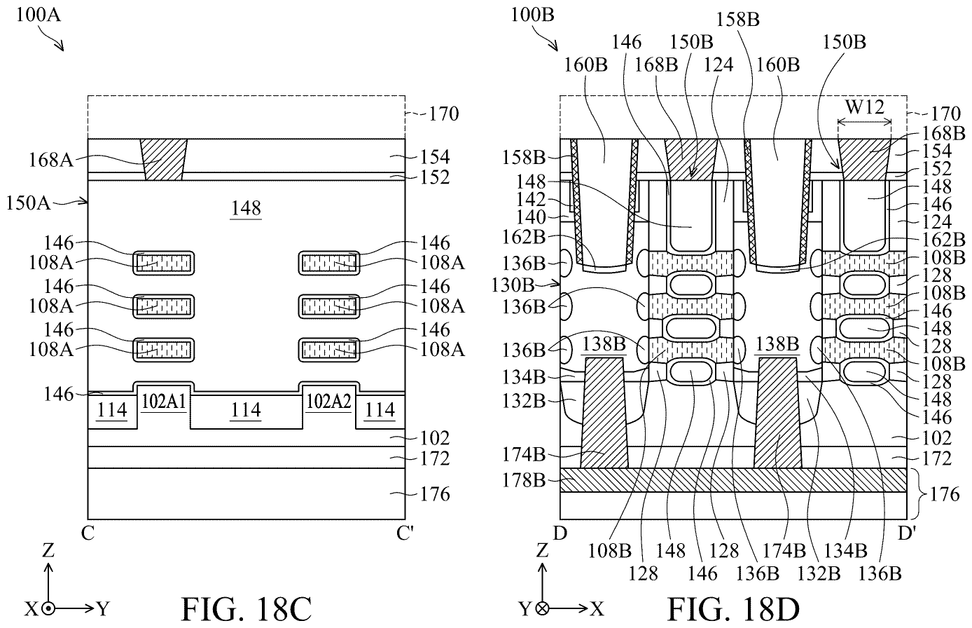

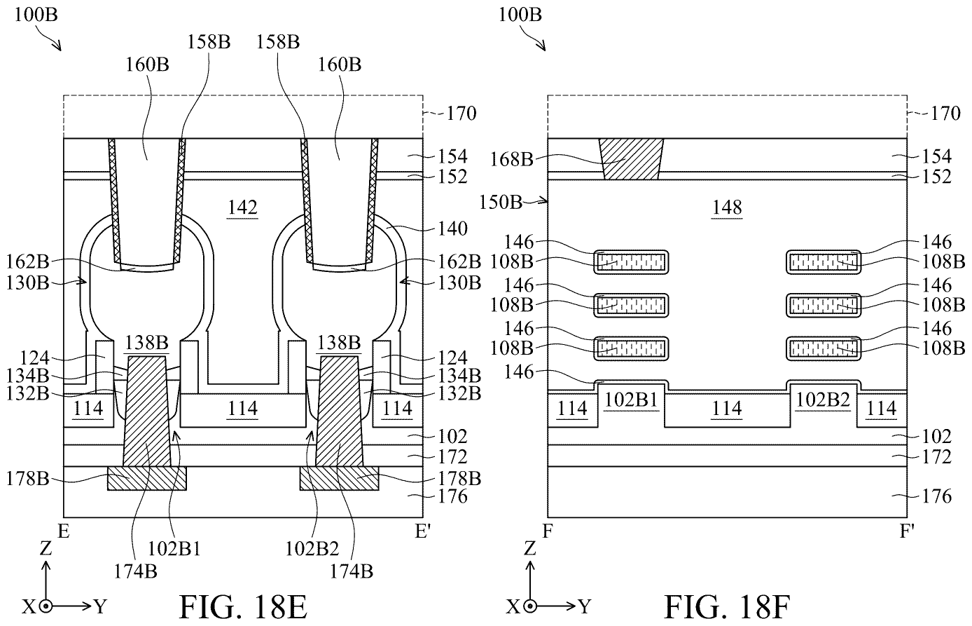

Referring to FIGS. 18A to 18F, gate vias 168A and 168B are formed to connect the gate structures 150A and 150B, respectively, in accordance with some embodiments. FIGS. 18A, 18B, and 18C are cross-sectional views of the semiconductor structure 100A along lines A-A′, B-B′, and C-C′ of FIG. 4A, respectively. FIGS. 18D, 18E, and 18F are cross-sectional views of the semiconductor structure 100B along lines D-D′, E-E′, and F-F′ of FIG. 4B, respectively.

In some embodiments, the gate vias 168A extend through the ILD layers 154 and the ESLs 152, and electrically connect to the gate structures 150A, as shown in FIGS. 18A and 18C. In some embodiments, the gate vias 168B extend through the ILD layers 154 and the ESLs 152, and electrically connect to the gate structures 150B, as shown in FIGS. 18D and 18E. In some embodiments, the width W12 of the gate vias 168B in the X-direction is greater than the width W11 of the gate vias 168A in the X-direction, as shown in FIGS. 18A and 18D. In some embodiments, the width W12 is greater than the width W11 by a range from about 1 nm to about 40 nm, such as by a range from about 1 nm to about 10 nm.

In some embodiments, the formation of the gate vias 168A and 168B includes forming via openings passing through the ILD layers 154 and the ESLs 152 to expose the gate structures 150A and 150B, and depositing a conductive material in the via openings. The conductive material may include Al, Cu, W, Co, Ti, Ta, Ru, Rh, Ir, Pt, TiN, TiAl, TiAlN, TaN, TaC, combinations thereof, or the like, although any suitable material may be used. The conductive material may be deposited using a deposition process such as sputtering, CVD, PVD, ALD, HDPCVD, MOCVD, RPCVD, PECVD, LPCVD, ALCVD, APCVD, FCVD, and/or other suitable method.

Still referring to FIGS. 18A to 18F, a frontside interconnection structure 170 is formed on the frontside of the workpiece 100, in accordance with some embodiments. For the purpose of simplicity and clarity, the frontside interconnection structure 170 is illustrated as a dashed box. In some embodiments, the frontside interconnection structure 170 includes one or more inter-metal dielectric (IMD) layers formed over the ILD layers 154, the source/drain contacts 160A and 160B, and the gate structures 150A and 150B. In some embodiments, the method and material used in forming the IMD layers are the same as or similar to those of the ILD layers 142, and are not repeated herein. The IMD layers may include multiple dielectric materials.

In some embodiments, the frontside interconnection structure 170 includes a plurality of vias (e.g., including source/drain vias, vias connecting between different metal layers, and the like) and a plurality of metal lines (e.g., including metal conductor) formed in the IMD layers. The plurality of vias and the plurality of metal lines connect the gate structures 150A and 150B and the source/drain contacts 160A and 160B to various circuit components, so as to constitute the interconnection of the semiconductor device. In some embodiments, the method and material used in forming the plurality of vias and the plurality of metal lines are the same as or similar to those of the source/drain contacts 160A and 160B, and are not repeated herein.

Still referring to FIGS. 18A to 18F, a portion of the substrate 102 is removed from the backside of the workpiece 100, and the ILD layers 172 are formed on backside surface of the substrate 102, in accordance with some embodiments. In other words, the substrate 102 is thinned and the ILD layers 172 are formed under the thinned substrate 102. Before thinning the substrate 102 and forming the ILD layers 172, the workpiece 100 may be flipped. For the purpose of simplicity, the sequent figures are shown without being flipped. In some embodiments, a carrier wafer may be bonded to the frontside of the workpiece 100 before flipping. In some embodiments, the substrate 102 is thinned (or partially removed) by a selective etching process or a CMP process.

After thinning the substrate 102, the ILD layers 172 may be formed under the thinned substrate 102, as shown in FIGS. 18A to 18F. In some embodiments, the method and material used in forming the ILD layers 172 are the same as or similar to those of the ILD layers 142, and are not repeated herein.

Still referring to FIGS. 18A to 18F, backside contact vias 174B are formed to connect the source/drain features 130B of the semiconductor structure 100B from backside, in accordance with some embodiments. In some embodiments, the backside contact vias 174B extend through the ILD layers 172, the substrate 102, the first epitaxial layers 132B, the bottom isolation layers 134B, and electrically connect to the third epitaxial layers 138B of the source/drain features 130B, as shown in FIGS. 18D and 18E. In some embodiments, the method and material used in forming the backside contact vias 174B are the same as or similar to those of the gate vias 168A and 168B or those of the source/drain contacts 160A and 160B, and are not repeated herein.

Still referring to FIGS. 18A to 18F, IMD layers 176 are formed under the ILD layers 172, and backside metal lines 178B are formed in the IMD layers 176 to connect the backside contact vias 174B, in accordance with some embodiments. In some embodiments, the IMD layers 176 are formed under the ILD layers 172 and the backside contact vias 174B. In some embodiments, the method and material used in forming the IMD layers 176 are the same as or similar to those of the ILD layers 142, and are not repeated herein.

In some embodiments, after the formation of the IMD layers 176, the backside metal lines 178B are formed in the IMD layers 176 and in contact with the backside contact vias 174B, so that the source/drain features 130B are connected to the backside metal lines 178B through the backside contact vias 174B. In some embodiments, the formation of the backside metal lines 178B includes forming trenches that extend lengthwise and expose the backside contact vias 174B, and depositing a conductive material in the trenches. The conductive material may include Al, Cu, W, Co, Ti, Ta, Ru, Rh, Ir, Pt, TiN, TiAl, TiAlN, TaN, TaC, combinations thereof, or the like, although any suitable material may be used. The conductive material may be deposited using a deposition process such as sputtering, CVD, PVD, ALD, HDPCVD, MOCVD, RPCVD, PECVD, LPCVD, ALCVD, APCVD, FCVD, and/or other suitable method.

In some embodiments, the semiconductor structure with large CPP includes backside interconnection, while the semiconductor structure with small CPP is free of backside interconnection. For example, the semiconductor structure 100B (i.e., large CPP) includes the backside contact vias 174B and the backside metal lines 178B, while the semiconductor structure 100A (i.e., small CPP) is free of the backside contact vias and the backside metal lines.

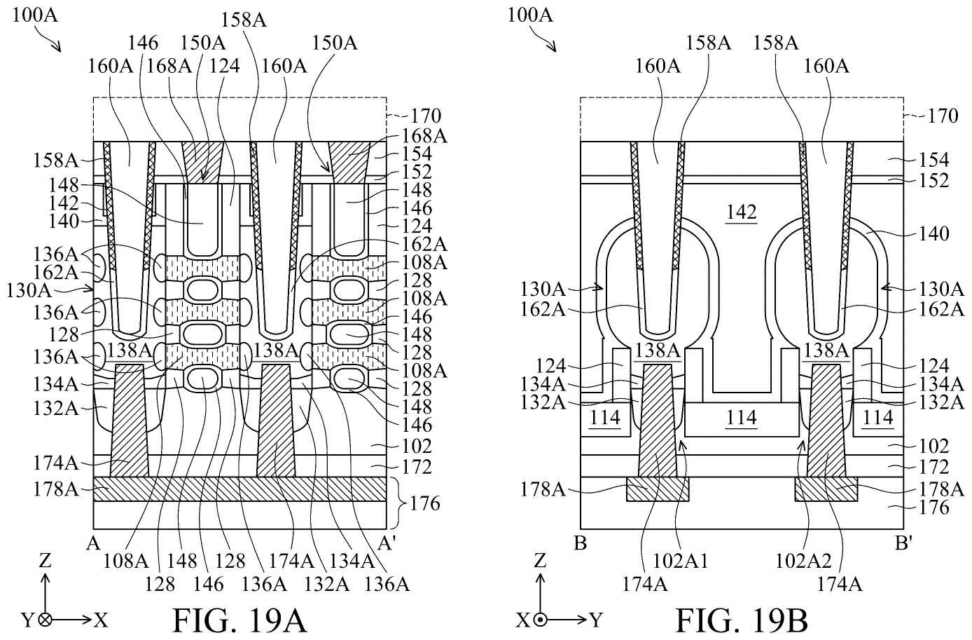

In other embodiments, the semiconductor structure 100A may also include backside interconnection. Referring to FIGS. 19A and 19B, backside contact vias 174A are formed to connect the source/drain features 130A of the semiconductor structure 100A from backside, and backside metal lines 178A are formed in the IMD layers 176 to connect the backside contact vias 174A, in accordance with some embodiments. In some embodiments, the backside contact vias 174A extend through the ILD layers 172, the substrate 102, the first epitaxial layers 132A, the bottom isolation layers 134A, and electrically connect to the third epitaxial layers 138A of the source/drain features 130A, as shown in FIGS. 19A and 19B. In some embodiments, the method and material used in forming the backside contact vias 174A are the same as or similar to those of the backside contact vias 174B, and are not repeated herein.

In some embodiments, the backside metal lines 178A are formed in the IMD layers 176 and in contact with the backside contact vias 174A, so that the source/drain features 130A are connected to the backside metal lines 178A through the backside contact vias 174A. In some embodiments, the method and material used in forming the backside metal lines 178A are the same as or similar to those of the backside metal lines 178B, and are not repeated herein. In the embodiments shown in FIGS. 19A and 19B, both the semiconductor structures with large CPP and small CPP include backside interconnection.

The embodiments discussed in FIGS. 1 to 19B provide methods to form structures including small CPP devices (e.g., the semiconductor structure 100A) and large CPP devices (e.g., the semiconductor structure 100B). The small CPP devices have S/D contacts that are deeper and/or narrower (e.g., the source/drain contacts 160A), and the large CPP devices have S/D contacts that are shallower and/or wider (e.g., the source/drain contacts 160B). In this way, in the small CPP devices, since the S/D contacts are narrower, the contact between the S/D contacts and the second epitaxial layers can be avoided. Therefore, the increased Rc in the small CPP devices can be avoided. Moreover, the contact between the S/D contacts and the inner gate portions can also be avoided, and thus the negative impact on the yield can be avoided. Further, since the S/D contacts are deeper, the contact area between the S/D contacts and the S/D features can be increased, so as to reduce the Rc in the small CPP devices.

On the other hand, since the S/D features (e.g., the source/drain features 130B) of the large CPP devices have large widths to allocate to the S/D contacts, the S/D contacts that are wider can be implemented in the large CPP devices, so as to increase the contact area between the S/D contacts and the S/D features without contacting the second epitaxial layers. Therefore, the Rc in the large CPP devices can be reduced. Meanwhile, since the S/D features have large widths, even if the positions of the S/D contacts that are shallower and/or wider are shifted during the process, the S/D contacts will still not contact the inner gate portions (e.g., the second inner portion 150B2). Therefore, the negative impact on the yield can be avoided. As a result, the device performances in the small CPP devices and the large CPP devices can be optimized individually and simultaneously.

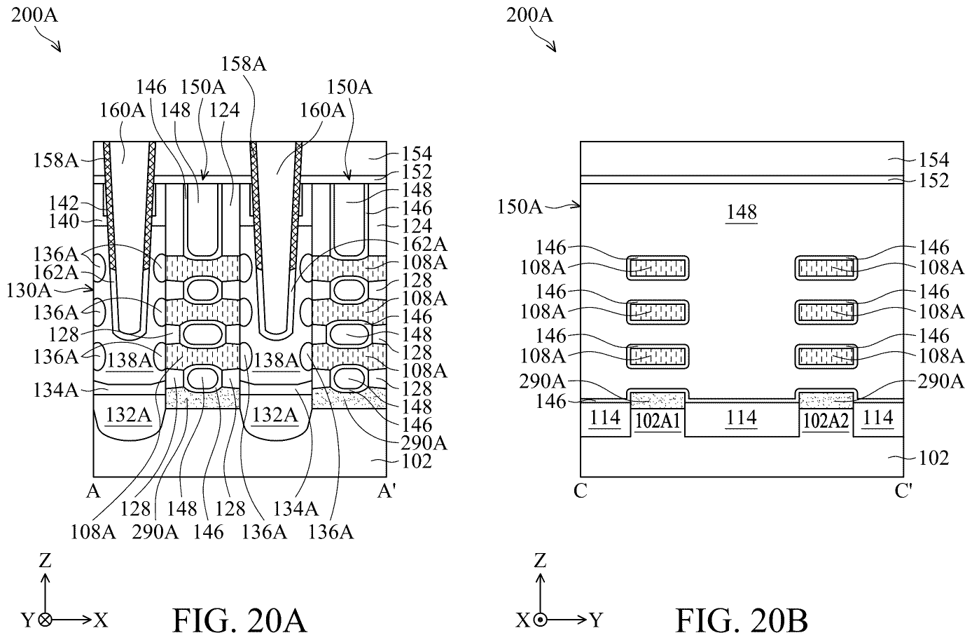

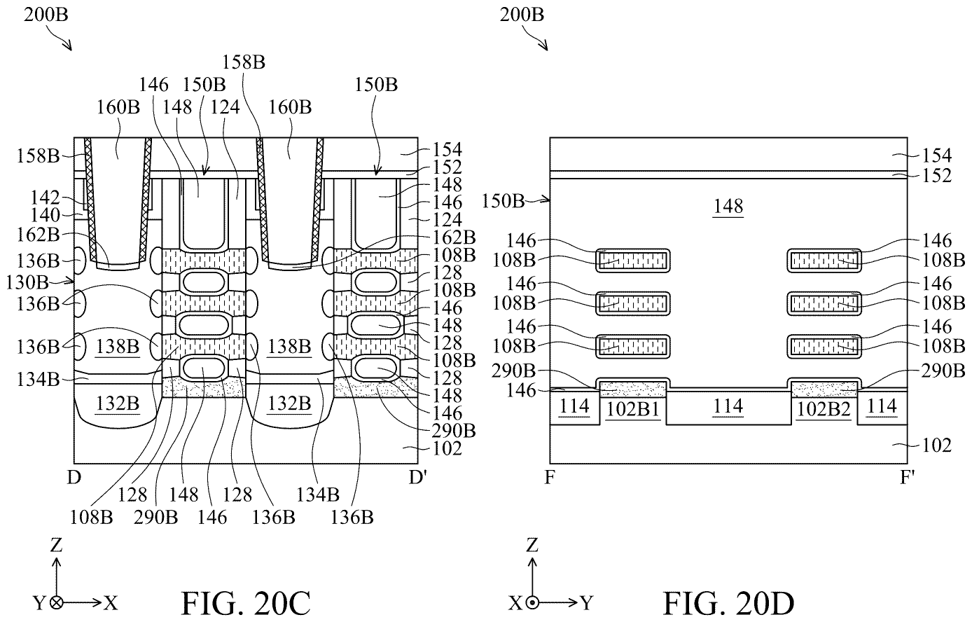

FIGS. 20A and 20B are an X-Z cross-sectional view and a Y-Z cross-sectional view of a semiconductor structure 200A along lines A-A′ and C-C′ of FIG. 4A, respectively, in accordance with alternative embodiments. FIGS. 20C and 20D are an X-Z cross-sectional view and a Y-Z cross-sectional view of a semiconductor structure 200B along lines D-D′ and F-F′ of FIG. 4B, respectively, in accordance with alternative embodiments. The semiconductor structure 200A shown in FIGS. 20A and 20B may be similar to the semiconductor structure 100A shown in FIGS. 17A and 17B, except the semiconductor structure 200A further includes gate bottom isolation layers 290A. The semiconductor structure 200B shown in FIGS. 20C and 20D may be similar to the semiconductor structure 100B shown in FIGS. 17C and 17D, except the semiconductor structure 200B further includes gate bottom isolation layers 290B.

In some embodiments, the gate bottom isolation layers 290A are formed over the substrate 102, below the semiconductor layers 108A, and below the gate structures 150A in the Z-direction, as shown in FIGS. 20A and 20B. In some embodiments, the gate bottom isolation layers 290A are vertically sandwiched between the substrate 102 and the gate structures 150A, so as to separate the gate structures 150A from the substrate 102 in the Z-direction. In some embodiments, the gate bottom isolation layers 290A are in contact with the bottommost pairs of inner spacers 128 in semiconductor structure 200A, and are vertically sandwiched between the bottommost pairs of inner spacers 128 and the substrate 102 in the Z-direction.

In some embodiments, the top surfaces of the gate bottom isolation layers 290A are lower than the top surfaces of the bottom isolation layers 134A and higher than the bottom surfaces of the bottom isolation layers 134A in the Z-direction. In these embodiments, the sidewalls of the gate bottom isolation layers 290A are in partial contact with the sidewalls of the bottom isolation layers 134A, and in partial contact with the sidewalls of the first epitaxial layers 132A, as shown in FIG. 20A. In some embodiments, the top surfaces of the gate bottom isolation layers 290A are higher than the top surfaces of the isolation structures 114, as shown in FIG. 20B. In some embodiments, the sidewalls of the bottom isolation layers 134A are in partial contact with the sidewalls of the bottommost pairs of inner spacers 128, and in partial contact with the sidewalls of the gate bottom isolation layer 290A, as shown in FIG. 20A.

In some embodiments, the gate bottom isolation layers 290B are formed over the substrate 102, below the semiconductor layers 108B, and below the gate structures 150B in the Z-direction, as shown in FIGS. 20C and 20D. In some embodiments, the gate bottom isolation layers 290B are vertically sandwiched between the substrate 102 and the gate structures 150B, so as to separate the gate structures 150B from the substrate 102 in the Z-direction. In some embodiments, the gate bottom isolation layers 290B are in contact with the bottommost pairs of inner spacers 128 in semiconductor structure 200B, and are vertically sandwiched between the bottommost pairs of inner spacers 128 and the substrate 102 in the Z-direction.

In some embodiments, the top surfaces of the gate bottom isolation layers 290B are lower than the top surfaces of the bottom isolation layers 134B and higher than the bottom surfaces of the bottom isolation layers 134B in the Z-direction. In these embodiments, the sidewalls of the gate bottom isolation layers 290B are in partial contact with the sidewalls of the bottom isolation layers 134B, and in partial contact with the sidewalls of the first epitaxial layers 132B, as shown in FIG. 20C. In some embodiments, the top surfaces of the gate bottom isolation layers 290B are higher than the top surfaces of the isolation structures 114, as shown in FIG. 20D. In some embodiments, the sidewalls of the bottom isolation layers 134B are in partial contact with the sidewalls of the bottommost pairs of inner spacers 128, and in partial contact with the sidewalls of the gate bottom isolation layer 290B, as shown in FIG. 20C.

In some embodiments, the formation of the gate bottom isolation layers 290A and 290B includes epitaxially growing an additional semiconductor layer under the stack 104 and on the substrate 102. More specifically, the additional semiconductor layer of SiGe with high Ge concentration is formed between the bottommost semiconductor layers 106 and the substrate 102. The semiconductor layers 106 may include SiGe and have a Ge concentration less than the additional semiconductor layer. Afterward, the additional semiconductor layer is patterned into a plurality of additional semiconductor layers in the fin structures 112.

After the formation of the source/drain trenches 126A and 126B, the additional semiconductor layers are exposed in the source/drain trenches 126A and 126B. Then, in some embodiments, a selective etching process is performed that selectively etches the additional semiconductor layers through the source/drain trenches 126A and 126B, with minimal etching (or substantially no etching) of the semiconductor layers 106 and 108 and the substrate 102. After the selective etching process, recesses for forming the gate bottom isolation layers are vertically formed between the semiconductor layers 106 and the substrate 102.

Then, in some embodiments, a deposition process is performed to form a dielectric material layer into the source/drain trenches 126A and 126B and the recesses. For example, the deposition process may be CVD, PVD, ALD, HDPCVD, MOCVD, RPCVD, PECVD, LPCVD, ALCVD, APCVD, other suitable methods, or combinations thereof. An etching back process is then performed that selectively etches the dielectric material layer to form gate bottom isolation layers 290A and 290B in the recesses with minimal etching (or substantially no etching) of the semiconductor layers 106 and 108, the substrate 102, the dummy gate structures 116, and the gate spacers 124. In some embodiments, each of the gate bottom isolation layers 290A and 290B may be a single dielectric layer or a multiple dielectric layers structure, and may include one or more dielectric materials, such as Si₃N₄, SiO₂, SiC, SiOC, SiON, SiOCN, carbon doped oxide, nitrogen doped oxide, porous oxide, or combinations thereof.

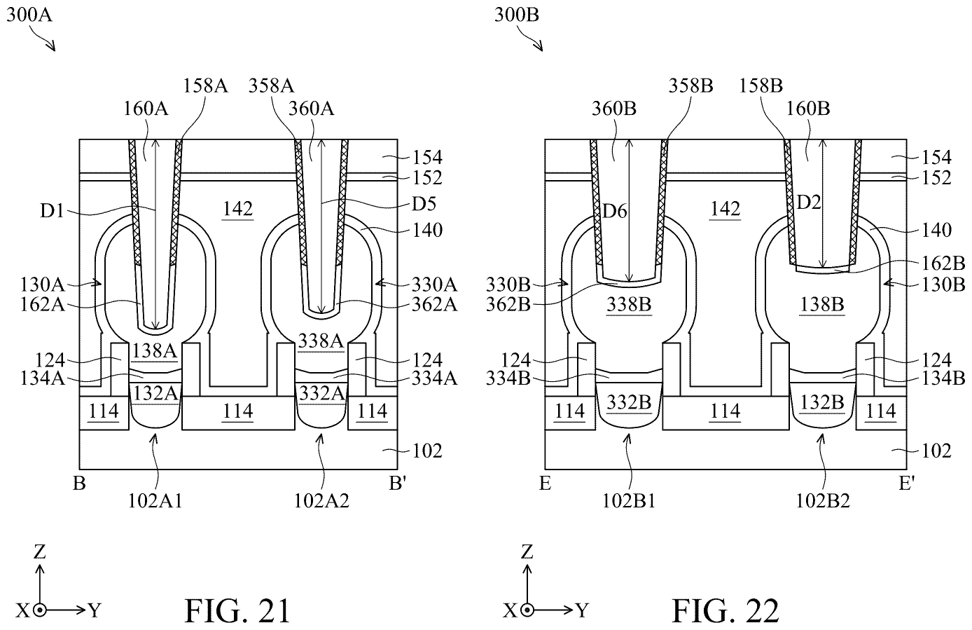

FIG. 21 is a Y-Z cross-sectional view of a semiconductor structure 300A along line B-B′ of FIG. 4A, in accordance with alternative embodiments. The semiconductor structure 300A shown in FIG. 21 may be similar to the semiconductor structure 100A shown in FIGS. 17A to 17B, except the source/drain features 130A and the source/drain contacts 160A formed in the fin structure 112A2 are replaced by the source/drain features 330A and the source/drain contacts 360A, respectively.

In some embodiments, each of the source/drain features 330A includes a first epitaxial layer 332A, a bottom isolation layer 334A, second epitaxial layers (not shown in FIG. 21), and a third epitaxial layer 338A that are the same as or similar to the first epitaxial layer 132A, the bottom isolation layer 134A, the second epitaxial layers 136A, and the third epitaxial layer 138A, respectively, as shown FIG. 21. The semiconductor structure 300A may further includes sidewall dielectric layers 358A that surround the upper portions of the source/drain contacts 360A, and includes silicide layers 362A that surround the lower portions and bottoms of the source/drain contacts 360A, as shown in FIG. 21.

In some embodiments, the source/drain contacts 360A extend shallower in the third epitaxial layers 338A of the source/drain features 330A than the source/drain contacts 160A extend in the third epitaxial layers 138A of the source/drain features 130A, as shown in FIG. 21. For example, the depth D5 of the source/drain contacts 360A is less than the depth D1 of the source/drain contacts 160A in the Z-direction. In some embodiments, the depth D1 is greater than the depth D5 by a range from about 2 nm to about 10 nm.

In some embodiments, the source/drain features 330A are p-type source/drain features for NFETs and the source/drain features 130A are n-type source/drain features for PFETs. In these embodiments, applying the shallower source/drain contacts 360A in PFETs and deeper source/drain contacts 160A in NFETs may provide more volume for p-type source/drain features (i.e., the source/drain features 330A). As a result, the channel strain of the PFETs can be enhanced, and thus the channel mobility and the DC performance of the PFETs can be improved. In this way, the performances of the PFETs and the NFETs may be optimized individually in small CPP devices (e.g., the semiconductor structure 300A).

FIG. 22 is a Y-Z cross-sectional view of a semiconductor structure 300B along line E-E′ of FIG. 4B, in accordance with alternative embodiments. The semiconductor structure 300B shown in FIG. 22 may be similar to the semiconductor structure 100B shown in FIGS. 17C to 17D, except the source/drain features 130B and the source/drain contacts 160B formed in the fin structure 112B1 are replaced by the source/drain features 330B and the source/drain contacts 360B, respectively.

In some embodiments, each of the source/drain features 330B includes a first epitaxial layer 332B, a bottom isolation layer 334B, second epitaxial layers (not shown in FIG. 22), and a third epitaxial layer 338B that are the same as or similar to the first epitaxial layer 132B, the bottom isolation layer 134B, the second epitaxial layers 136B, and the third epitaxial layer 138B, respectively, as shown FIG. 22. The semiconductor structure 300B may further includes sidewall dielectric layers 358B that surround the upper portions of the source/drain contacts 360B, and includes silicide layers 362B that surround the lower portions and bottoms of the source/drain contacts 360B, as shown in FIG. 22.

In some embodiments, the source/drain contacts 360B extend deeper in the third epitaxial layers 338B of the source/drain features 330B than the source/drain contacts 160B extend in the third epitaxial layers 138B of the source/drain features 130B, as shown in FIG. 22. For example, the depth D6 of the source/drain contacts 360B is greater than the depth D2 of the source/drain contacts 160B in the Z-direction. In some embodiments, the depth D6 is greater than the depth D2 by a range from about 2 nm to about 10 nm.

In some embodiments, the source/drain features 330B are n-type source/drain features for NFETs and the source/drain features 130B are p-type source/drain features for PFETs. In these embodiments, applying the shallower source/drain contacts 160B in PFETs and deeper source/drain contacts 360B in NFETs may provide more volume for p-type source/drain features (i.e., the source/drain features 130B). As a result, the channel strain of the PFETs can be enhanced, and thus the channel mobility and the DC performance of the PFETs can be improved. In this way, the performances of the PFETs and the NFETs may be optimized individually in large CPP devices (e.g., the semiconductor structure 300B).

Although FIGS. 5A to 22 show that two vertical stacks of the nanostructures (e.g., semiconductor layers 108A or 108B) and two corresponding gate structures (e.g., gate structures 150A or 150B) and two source/drain features (e.g., source/drain features 130A, 130B, 330A, and 330B) are formed in one fin structure (e.g., fin structure 112), which are for illustrative purposes only and are not intended to limit the present disclosure. For example, an additional source/drain feature and corresponding elements (e.g., source/drain contact, silicide layer) may be formed in the fin structure 112, such that each vertical stack of the semiconductor layers 108A or 108B are between two source/drain features. However, the present disclosure is not limited to two vertical stacks of the nanostructures and two or three source/drain features, the number of the vertical stacks of the nanostructures and the number of the source/drain features depend on the design requirements.

The embodiments disclosed herein relate to semiconductor structures and their forming methods, and more particularly to methods and semiconductor structures that include forming a small CPP structure with S/D contacts that are deeper and/or narrower, and forming a large CPP structure with S/D contacts that are shallower and/or wider. In this way, in the small CPP structure, since the S/D contacts are narrower, the contact between the S/D contacts and the second epitaxial layers can be avoided. Therefore, the increased Rc in the small CPP structure can be avoided. Moreover, the contact between the S/D contacts and the inner gate portions can also be avoided, and thus the negative impact on the yield can be avoided. Further, since the S/D contacts are deeper, the contact area between the S/D contacts and the S/D features can be increased, so as to reduce the Rc in the small CPP structure. On the other hand, since the S/D features of the large CPP structure have large widths to allocate to the S/D contacts, the S/D contacts that are wider can be implemented in the large CPP structure, so as to increase the contact area between the S/D contacts and the S/D features without contacting the second epitaxial layers. Therefore, the Rc in the large CPP structure can be reduced. Meanwhile, even if the positions of the S/D contacts that are shallower and/or wider are shifted during the process, the S/D contacts will still not contact the inner gate portions due to the S/D features with large widths and the S/D contacts with shallow depths. Therefore, the negative impact on the yield can be avoided. As a result, the device performances in the small CPP structure and the large CPP structure can be optimized individually and simultaneously.

In one exemplary aspect, the present disclosure is directed to a semiconductor structure. The semiconductor structure includes a first transistor and a second transistor over a substrate. The first transistor includes first nanostructures spaced apart from each other in a vertical direction and a first gate structure wrapped around each of the first nanostructures. The first transistor further includes first source/drain features attached to opposite sides of the first nanostructures, first source/drain contacts partially extending into and electrically connected to the first source/drain features, and first silicide layers formed on sidewalls and bottoms of lower portions of the first source/drain contacts. The bottom surfaces of the first silicide layers includes a curved profile. A conductivity of the first source/drain contacts is greater than a conductivity of the first source/drain features and a conductivity of the first silicide layers. The second transistor includes second nanostructures spaced apart from each other in the vertical direction, and a second gate structure wrapped around each of the second nanostructures. The second transistor further includes second source/drain features attached to opposite sides of the second nanostructures, and second source/drain contacts partially extending into and electrically connected to the second source/drain features. The second dimension of the second source/drain features is greater than the first dimension of the first source/drain features. The second width of the second source/drain contacts is greater than the first width of the first source/drain contacts, and the second depth of the second source/drain contacts is less than the first depth of the first source/drain contacts.

In another exemplary aspect, the present disclosure is directed to a semiconductor structure. The semiconductor structure includes first nanostructures spaced apart from each other in a vertical direction, a first gate structure wrapped around each of the first nanostructures, first source/drain features formed on opposite sides of the first gate structure in a horizontal direction, and first source/drain contacts extending into the first source/drain features and including upper portions and lower portions. In the vertical direction, bottom surfaces of the upper portions are higher than a top surface of a second topmost one of the first nanostructures, and bottom surfaces of the lower portions are lower than a bottom surface of the second topmost one of the first nanostructures. The semiconductor structure also includes second nanostructures spaced apart from each other in the vertical direction, a second gate structure wrapped around each of the second nanostructures, and second source/drain features formed on opposite sides of the second gate structure in the horizontal direction. The second dimension of the second source/drain features is greater than the first dimension of the first source/drain features. The semiconductor structure further includes a contact etch stop layer (CESL) formed on the second source/drain features, an interlayer dielectric (ILD) layer formed on the CESL, and second source/drain contacts extending through the ILD layer and the CESL and into the second source/drain features. In the vertical direction, bottom surfaces of the second source/drain contacts are higher than a top surface of a second topmost one of the second nanostructures. The second source/drain contacts are surrounded by the CESL and the ILD layer. The second source/drain contacts are spaced apart from the second gate structure by the CESL and the ILD layer. The second width of the second source/drain contacts is greater than the first width of the first source/drain contacts in the horizontal direction.

In yet another exemplary aspect, the present disclosure is directed to a method of forming a semiconductor structure. The method includes respectively forming a first fin structure and a second fin structure in a first region and a second region of a substrate, forming a first source/drain feature and a second source/drain feature in the first fin structure, and forming a third source/drain feature and a fourth source/drain feature in the second fin structure. Each of the first fin structure and the second fin structure includes first semiconductor layers and second semiconductor layers alternately stacked. The method further includes forming a first gate structure between the first source/drain feature and the second source/drain feature, forming a second gate structure between the third source/drain feature and the fourth source/drain feature, forming a first trench over and exposing the first source/drain feature, and forming a second trench over and exposing the third source/drain feature. The second width of the second trench is greater than the first width of the first trench. The method further includes forming a hard mask layer in the second region of the substrate to cover a surface of the second trench, and etching the first source/drain feature through the first trench to extend the first trench in a vertical direction. The bottom surface of the extended first trench is lower than the bottom surface of the second trench in the vertical direction. The method further includes removing the hard mask layer, and depositing a conductive material in the first trench and the second trench to form a first source/drain contact and a second source/drain contact.

In yet another exemplary aspect, the present disclosure is directed to a semiconductor structure. The semiconductor structure includes a first transistor in a first region of a substrate and a second transistor in a second region of the substrate. The first transistor includes first nanostructures vertically arranged in a vertical direction, a first gate structure wrapped around each of the first nanostructures, and first source/drain features formed on opposite sides of the first gate structure and connected to the first nanostructures. The first transistor further includes first bottom isolation layers formed on bottoms of the first source/drain features, and first source/drain contacts partially extending into and electrically connected to the first source/drain features. The second transistor includes second nanostructures vertically arranged in the vertical direction, a second gate structure wrapped around each of the second nanostructures, and second source/drain features formed on opposite sides of the second gate structure and connected to the second nanostructures. The second transistor further includes second bottom isolation layers formed on bottoms of the second source/drain features, and second source/drain contacts partially extending into and electrically connected to the second source/drain features. The second dimension of the second source/drain features is greater than the first dimension of the first source/drain features. In the vertical direction, a first distance between the first bottom isolation layers and the first source/drain contacts is less than a second distance between the second bottom isolation layers and the second source/drain contacts.

In some embodiments, a second width of the second source/drain contacts is greater than a first width of the first source/drain contacts, and a second depth of the second source/drain contacts is less than a first depth of the first source/drain contacts in the vertical direction.

In some embodiments, the semiconductor structure further includes first sidewall dielectric layers formed on sidewalls of upper portions of the first source/drain contacts, first silicide layers formed on sidewalls of lower portions of the first source/drain contacts, and second sidewall dielectric layers formed on sidewalls of the second source/drain contacts. The second depth of the second source/drain contacts is substantially the same as the first depth of the upper portions of the first source/drain contacts.

In some embodiments, the semiconductor structure further includes backside source/drain vias, extending through the substrate and the second bottom isolation layers and into the second source/drain features, so as to connect the second source/drain features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor over a substrate, wherein the first transistor comprises:
first nanostructures, spaced apart from each other in a vertical direction;
a first gate structure, wrapped around each of the first nanostructures;
first source/drain features, attached to opposite sides of the first nanostructures;
first source/drain contacts, partially extending into and electrically connected to the first source/drain features; and
first silicide layers, formed on sidewalls and bottoms of lower portions of the first source/drain contacts, wherein bottom surfaces of the first silicide layers comprise a curved profile, and wherein a conductivity of the first source/drain contacts is greater than a conductivity of the first source/drain features and a conductivity of the first silicide layers; and
a second transistor over the substrate, wherein the second transistor comprises:
second nanostructures, spaced apart from each other in the vertical direction;
a second gate structure, wrapped around each of the second nanostructures;
second source/drain features, attached to opposite sides of the second nanostructures; and
second source/drain contacts, partially extending into and electrically connected to the second source/drain features,
wherein a second dimension of the second source/drain features is greater than a first dimension of the first source/drain features,
wherein a second width of the second source/drain contacts is greater than a first width of the first source/drain contacts, and wherein a second depth of the second source/drain contacts is less than a first depth of the first source/drain contacts.

2. The semiconductor structure of claim 1,
wherein bottom surfaces of the first source/drain contacts are lower than a bottom surface of a second topmost one of the first nanostructures in the vertical direction, and
wherein bottom surfaces of the second source/drain contacts are higher than a bottom surface of a second topmost one of the second nanostructures in the vertical direction.

3. The semiconductor structure of claim 1, further comprising:
a first gate via, formed on and in contact with the first gate structure; and
a second gate via, formed on and in contact with the second gate structure,
wherein a fourth width of the second gate via is greater than a third width of the first gate via.

4. The semiconductor structure of claim 1, wherein a second distance between middle lines of two adjacent ones of the second source/drain features is greater than a first distance between middle lines of the two adjacent ones of the first source/drain features.

5. The semiconductor structure of claim 1,
wherein the first source/drain features comprise first epitaxial layers formed on end portions of the first nanostructures and second epitaxial layers formed on the first epitaxial layers, and
wherein the first source/drain contacts are in contact with the second epitaxial layers and spaced apart from the first epitaxial layers by the second epitaxial layers.

6. The semiconductor structure of claim 1, further comprising:
first sidewall dielectric layers, formed on sidewalls of upper portions of the first source/drain contacts.

7. The semiconductor structure of claim 1, further comprising:
backside source/drain vias, extending through the substrate and into the second source/drain features, so as to connect the second source/drain features.

8. A semiconductor structure, comprising:
first nanostructures, spaced apart from each other in a vertical direction;
a first gate structure, wrapped around each of the first nanostructures;
first source/drain features, formed on opposite sides of the first gate structure in a horizontal direction;
first source/drain contacts, extending into the first source/drain features and comprising upper portions and lower portions, wherein in the vertical direction, bottom surfaces of the upper portions are higher than a top surface of a second topmost one of the first nanostructures and bottom surfaces of the lower portions are lower than a bottom surface of the second topmost one of the first nanostructures;
second nanostructures, spaced apart from each other in the vertical direction;
a second gate structure, wrapped around each of the second nanostructures;
second source/drain features, formed on opposite sides of the second gate structure in the horizontal direction, wherein a second dimension of the second source/drain features is greater than a first dimension of the first source/drain features;
a contact etch stop layer (CESL), formed on the second source/drain features;
an interlayer dielectric (ILD) layer, formed on the CESL; and
second source/drain contacts, extending through the ILD layer and the CESL and into the second source/drain features, wherein in the vertical direction, bottom surfaces of the second source/drain contacts are higher than a top surface of a second topmost one of the second nanostructures, wherein the second source/drain contacts are surrounded by the CESL and the ILD layer, and wherein the second source/drain contacts are spaced apart from the second gate structure by the CESL and the ILD layer,
wherein a second width of the second source/drain contacts is greater than a first width of the first source/drain contacts in the horizontal direction.

9. The semiconductor structure of claim 8, further comprising:
first inner spacers, formed below the second topmost one of the first nanostructures, wherein the first gate structure comprises a first inner portion formed between the first inner spacers; and
second inner spacers, formed below the second topmost one of the second nanostructures, wherein the second gate structure comprises a second inner portion formed between the second inner spacers,
wherein a second length of the second inner portion is greater than a first length of the first inner portion in the horizontal direction.

10. The semiconductor structure of claim 9, further comprising:
third inner spacers, formed over the second topmost one of the first nanostructures, wherein the first gate structure comprises a third inner portion formed between the third inner spacers,
wherein a third length of the third inner portion is less than the first length of the first inner portion in the horizontal direction.

11. The semiconductor structure of claim 8, further comprising:
first bottom isolation layers and second bottom isolation layers, formed on bottoms of the first source/drain features and bottoms of the second source/drain features, respectively,
wherein in the vertical direction, a first distance between the first bottom isolation layers and the first source/drain contacts is less than a second distance between the second bottom isolation layers and the second source/drain contacts.

12. The semiconductor structure of claim 8, further comprising:
a first gate bottom isolation layer, formed below the first nanostructures and on a bottom of the first gate structure; and
a second gate bottom isolation layer, formed below the second nanostructures and on a bottom of the second gate structure.

13. The semiconductor structure of claim 8, further comprising:
third nanostructures, spaced apart from each other in the vertical direction;
a third gate structure, wrapped around each of the third nanostructures;
third source/drain features, formed on opposite sides of the third gate structure in the horizontal direction, wherein a third dimension of the third source/drain features is substantially the same as the first dimension of the first source/drain features; and
third source/drain contacts, extending into the third source/drain features,
wherein in the vertical direction, a third depth of the third source/drain contacts is less than a first depth of the first source/drain contacts and is greater than a second depth of the second source/drain contacts.

14. The semiconductor structure of claim 13, wherein the first source/drain features are n-type source/drain features in an n-type transistor, and the third source/drain features are p-type source/drain features in a p-type transistor.

15. The semiconductor structure of claim 8,
wherein the first source/drain features comprise first epitaxial layers formed on end portions of the first nanostructures and second epitaxial layers formed on the first epitaxial layers, and
wherein the first source/drain contacts are in contact with the second epitaxial layers and spaced apart from the first epitaxial layers by the second epitaxial layers.

16. The semiconductor structure of claim 8, further comprising:
first sidewall dielectric layers, formed on sidewalls of the upper portions of the first source/drain contacts; and
first silicide layers, formed on sidewalls and the bottom surfaces of the lower portions of the first source/drain contacts.

17. A method of forming a semiconductor structure, comprising:
forming a first fin structure and a second fin structure in a first region and a second region of a substrate, respectively, wherein each of the first fin structure and the second fin structure comprises first semiconductor layers and second semiconductor layers alternately stacked;
forming a first source/drain feature and a second source/drain feature in the first fin structure, and forming a third source/drain feature and a fourth source/drain feature in the second fin structure;
forming a first gate structure between the first source/drain feature and the second source/drain feature, and forming a second gate structure between the third source/drain feature and the fourth source/drain feature;
forming a first trench over and exposing the first source/drain feature, and forming a second trench over and exposing the third source/drain feature, wherein a second width of the second trench is greater than a first width of the first trench;
forming a hard mask layer in the second region of the substrate to cover a surface of the second trench;
etching the first source/drain feature through the first trench to extend the first trench in a vertical direction, wherein a bottom surface of the extended first trench is lower than a bottom surface of the second trench in the vertical direction;
removing the hard mask layer; and
depositing a conductive material in the first trench and the second trench to form a first source/drain contact and a second source/drain contact.

18. The method of claim 17, further comprising:
forming a hard mask material layer in the first region and the second region;
forming a patterned photoresist layer to cover the hard mask material layer in the second region; and
removing the hard mask material layer from the first region to form the hard mask layer in the second region, such that the second trench is covered by the hard mask layer and the first source/drain feature is exposed by the first trench.

19. The method of claim 17,
wherein after extending the first trench, the bottom surface of the extended first trench is lower than a bottom surface of a second topmost one of the second semiconductor layers in the first fin structure in the vertical direction,
wherein the bottom surface of the second trench is higher than a top surface of a second topmost one of the second semiconductor layers in the second fin structure in the vertical direction.

20. The method of claim 17, further comprising:
forming a fifth source/drain feature in the first fin structure and a third gate structure between the second source/drain feature and the fifth source/drain feature; and
forming a sixth source/drain feature in the second fin structure and a fourth gate structure between the fourth source/drain feature and the sixth source/drain feature,
wherein a first distance between a middle line of the first gate structure and a middle line of the third gate structure is smaller than a second distance between a middle line of the second gate structure and a middle line of the fourth gate structure.
